(19) United States
(12) Patent Application Publication
(10) Pub. No.: US 2026/0130036 A1
(43) Pub. Date: May 7, 2026

(54) DISPLAY PANEL AND DISPLAY DEVICE

(71) Applicant: Tianma Advanced Display Technology Institute (Xiamen) Co., Ltd., Xiamen (CN)

(72) Inventors: Peixuan CHEN, Xiamen (CN); Meng WANG, Xiamen (CN)

(73) Assignee: Tianma Advanced Display Technology Institute (Xiamen) Co., Ltd., Xiamen (CN)

(21) Appl. No.: 19/436,273

(22) Filed: Dec. 30, 2025

(30) Foreign Application Priority Data
Jul. 1, 2025 (CN) 202510904983.X

(51) Int. Cl. H10H 29/855; H10H 29/34; H10H 29/852

(52) U.S. Cl. CPC H10H 29/855; H10H 29/34; H10H 29/852

(57) ABSTRACT

Provided are a display panel and a display device. The display panel includes an array substrate, a light-shielding layer and multiple light-emitting elements. The multiple light-emitting elements are disposed on the array substrate, and the light-shielding layer is located on one side of the multiple light-emitting elements facing away from the array substrate. The light-shielding layer includes multiple openings. In a thickness direction of the display panel, the multiple openings at least partially overlap the multiple light-emitting elements in one-to-one correspondence, and a center of a light-emitting element among the multiple light-emitting elements overlaps a respective one of the multiple openings and does not overlap the light-shielding layer. In the display panel, the light-shielding layer with the openings is disposed on a light emission side of the light-emitting elements.

### CROSS-REFERENCE TO RELATED APPLICATIONS

This application claims priority to Chinese Patent Application No. 202510904983.X filed July 01, 2025, the disclosure of which is incorporated herein by reference in its entirety.

### TECHNICAL FIELD

Embodiments of the present disclosure relate to the field of display technologies and, in particular, to a display panel and a display device.

### BACKGROUND

At present, display technology has penetrated into all aspects of people's daily life. To keep pace with this trend, more and more materials and technologies are used in display screens, thereby bringing great convenience to people's daily life and work. The display of micro light-emitting diodes (micro-LEDs) is considered to be the next generation display technology due to characteristics such as ultra-high brightness, a high resolution, a high contrast ratio, fast response time, low power consumption, high transparency and a miniaturized size.

In the related art, thanks to the miniaturization of the size of the micro-LED chip, micro-LED transparent display screens can achieve a larger proportion of an area of a transparent region and higher transparency so that the transparent display of the micro-LEDs has a wide range of application scenarios such as the transparent display in front of the driver's seat of the vehicle and the projection display of the front windshield of the vehicle. However, since the micro-LED transparent display screen has a relatively divergent light pattern of light emission, the wide-angle beams are easily reflected by objects such as the front windshield and side window glass of the vehicle and enter the human eyes to form a reflection and generate a virtual image, which interferes with the driver's observation of the scene outside the vehicle and affects driving safety.

### SUMMARY

Embodiments of the present disclosure provide a display panel and a display device. A light-shielding layer with openings is disposed at a light emission side of light-emitting elements. The light-shielding layer can effectively adjust an angle of light emitted from the light-emitting element to meet different requirements for light emission.

In a first aspect, the embodiments of the present disclosure provide a display panel. The display panel includes an array substrate, a light-shielding layer and multiple light-emitting elements.

The multiple light-emitting elements are disposed on the array substrate, and the light-shielding layer is located on one side of the multiple light-emitting elements facing away from the array substrate.

The light-shielding layer includes multiple openings. In a thickness direction of the display panel, the multiple openings at least partially overlap the multiple light-emitting elements in one-to-one correspondence, and a center of a light-emitting element among the multiple light-emitting elements overlaps a respective one of the multiple openings and does not overlap the light-shielding layer.

In a second aspect, the embodiments of the present disclosure further provide a display device. The display device includes any display panel described in the first aspect.

### BRIEF DESCRIPTION OF DRAWINGS

FIG. 1 is a plan view of a light-emitting element in a display panel according to an embodiment of the present disclosure.

FIG. 2 is a top view of a display panel according to an embodiment of the present disclosure.

FIG. 3 is a section view taken along a section line AA' of the display panel of FIG. 2.

FIG. 4 is a section view taken along a section line BB' of the display panel of FIG. 2.

FIG. 5 is a top view of another display panel according to an embodiment of the present disclosure.

FIG. 6 is a section view taken along a section line CC' of the display panel of FIG. 5.

FIG. 7 is a section view taken along a section line EE' of the display panel of FIG. 5.

FIG. 8 is a top view of another display panel according to an embodiment of the present disclosure.

FIG. 9 is a section view taken along a section line FF' of the display panel of FIG. 8.

FIG. 10 is a section view taken along a section line GG' of the display panel of FIG. 8.

FIG. 11 is a top view of another display panel according to an embodiment of the present disclosure.

FIG. 12 is a top view of another display panel according to an embodiment of the present disclosure.

FIG. 13 is a section view taken along a section line RR' of the display panel of FIG. 12.

FIG. 14 is a section view taken along a section line PP' of the display panel of FIG. 12.

FIG. 15 is an enlarged view of a first light-emitting element and a first opening in the display panel shown in FIG. 2.

FIG. 16 is a top view of another display panel according to an embodiment of the present disclosure.

FIG. 17 is a section view taken along a section line QQ' of the display panel of FIG. 16.

FIG. 18 is a top view of another display panel according to an embodiment of the present disclosure.

FIG. 19 is a top view of another display panel according to an embodiment of the present disclosure.

FIG. 20 is another section view taken along a section line AA' of the display panel of FIG. 2.

FIG. 21 is a diagram illustrating the structure of a display device according to an embodiment of the present disclosure.

### DETAILED DESCRIPTION

The present disclosure is further described in detail below in conjunction with the drawings and embodiments. It is to be understood that the embodiments described herein are intended to illustrate the present disclosure and not to limit the present disclosure. Additionally, it is to be noted that for ease of description, only part, not all, of structures related to the present disclosure are illustrated in the drawings.

Those skilled in the art has found through researches that in the application scenarios of the display of the micro-LEDs, since the emitted light from the micro-LED has a relatively divergent pattern, this type of wide-angle beams are easily reflected by other objects after emission, enter the human eyes to form a reflection and generate a virtual image, and interfere with the user's line of sight. For example, in application scenarios such as the transparent display in front of the driver's seat of the vehicle and the projection display of the front windshield of the vehicle, the wide-angle beams emitted from the micro-LED display panel are easily reflected by the front windshield and/or side window glass of the vehicle and enter the human eyes to form a reflection and generate a virtual image, which interferes with the driver's observation of the scene outside the vehicle and affects driving safety. A conventional method for limiting the wide-angle beams emitted from the micro-LED display panel is to stick a privacy film on a screen surface of the micro-LED display panel. However, after the superimposition of a periodic structure of the privacy film and a periodic structure of screen pixels, moire is easily generated, resulting in a serious effect on a viewing effect. In addition, for the driver's seat of the vehicle, directions of the front windshield and the side window glass needs to limit the wide-angle beams emitted from the micro-LED display panel. However, the case where the screen of the micro-LED display panel is viewed from a front passenger seat of the vehicle is considered, and the front passenger seat can allow the existence of the wide-angle beams emitted from the micro-LED display panel.

Based on the above-mentioned technical problems, the embodiments of the present disclosure provide a display panel. The display panel includes an array substrate, a light-shielding layer and multiple light-emitting elements. The multiple light-emitting elements are disposed on the array substrate, and the light-shielding layer is located on one side of the multiple light-emitting elements facing away from the array substrate. The light-shielding layer includes multiple openings. In a thickness direction of the display panel, the multiple openings at least partially overlap the multiple light-emitting elements in one-to-one correspondence, and a center of a light-emitting element among the multiple light-emitting elements overlaps a respective one of the multiple openings and does not overlap the light-shielding layer.

According to the technical solutions in the embodiments of the present disclosure, in the display panel, the light-shielding layer with the openings is disposed on a light emission side of the light-emitting elements. The light-shielding layer can effectively adjust an angle of light emitted from the light-emitting element to meet different requirements for light emission. For example, the wide-angle beams from the light-emitting element are shielded, thereby avoiding the problem that this type of wide-angle beams are easily reflected by other objects after emission, enter the human eyes to form a reflection and generate a virtual image and interfere with the user's line of sight. Moreover, the openings on the light-shielding layer at least partially overlap the light-emitting elements in one-to-one correspondence. In this manner, the opening can ensure the emission of on-axis beams or a small viewing angle from the light-emitting element, and when the user views the display panel at a frontal or approximately frontal viewing angle, the display panel is in a normal display state, ensuring the user's good viewing experience of the display panel and an undisturbed field of view for observation of an external environment of the display panel.

The preceding is the core idea of the present disclosure. The technical solutions in the embodiments of the present disclosure are described clearly and completely hereinafter in conjunction with the drawings in the embodiments of the present disclosure. Based on the embodiments of the present disclosure, all other embodiments obtained by those of ordinary skill in the art without any creative efforts are within the scope of the present disclosure.

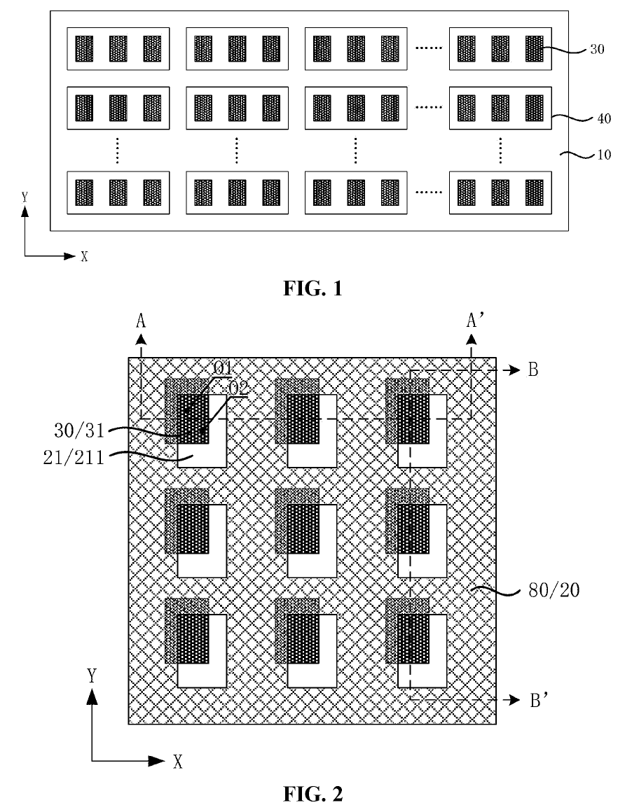

It is to be firstly noted that FIG. 1 is a plan view of a light-emitting element in a display panel according to an embodiment of the present disclosure. As shown in FIG. 1, the display panel includes an array substrate 10 and multiple light-emitting elements 30, and each light-emitting element 30 is disposed on a surface at one side of the array substrate 10. For example, the array substrate 10 may be a rigid substrate or a flexible substrate. A specific material is not limited and may be selected and set according to an actual need. For example, the light-emitting element 30 may be displayed as a sub-pixel. Moreover, the light-emitting element 30 may include, but is not limited to, a micro-LED or a mini-LED for a good display effect, and when the light-emitting element 30 is a micro-LED or a mini-LED, each light-emitting element 30 is a separate chip and needs to be transferred to a surface on one side of the array substrate 10 through mass transfer. For example, the array substrate 10 may include a base substrate and a metal circuit layer. The metal circuit layer is located on a surface on one side of the base substrate, and each light-emitting element 30 is located on a surface on one side of the metal circuit layer facing away from the base substrate and electrically connected to the metal circuit layer. In this manner, the metal circuit layer can provide a corresponding control signal or power signal to each light-emitting element 30 to ensure the normal operation of each light-emitting element 30. For example, the metal circuit layer may consist of a thin-film transistor (TFT) and a capacitor. The metal circuit layer may also be understood as a pixel circuit layer and is not shown in detail in FIG. 1. The display panel may further include other film structures, and only the arrangement of each light-emitting element 30 on a surface on one side of the array substrate 10 is briefly described in FIG. 1.

With continued reference to FIG. 1, the display panel includes multiple pixel units 40, and the pixel units 40 are arranged in an array along a first direction X and a second direction Y. In other words, the display panel may consist of multiple pixel units 40 arranged in an array. The first direction X and the second direction Y are parallel to the array substrate 10 and intersect with each other. FIG. 1 illustrates that the first direction X is perpendicular to the second direction Y, but the present disclosure is not limited thereto in practice. In an embodiment, the first direction X may be understood as a row direction of the pixel unit 40, and the second direction Y may be understood as a column direction of the pixel unit 40; in another embodiment, the first direction X may also be understood as the column direction of the pixel unit 40, and the second direction Y may also be understood as the row direction of the pixel unit 40. This is not limited in this embodiment. For ease of description, in the embodiments of the present disclosure, the first direction X being the row direction of the pixel unit 40 and the second direction Y being the column direction of the pixel unit 40 are used as an example for illustratively describing the technical solutions in the embodiments of the present disclosure.

Each pixel unit 40 includes at least two light-emitting elements 30 sequentially arranged in the first direction X. For example, the pixel unit 40 may include three light-emitting elements 30 having different emission colors sequentially arranged in the first direction X. In this manner, light-emitting elements 30 having different emission colors in each pixel unit 40 are sequentially arranged in the first direction X, and light-emitting elements 30 sequentially arranged in the second direction Y have the same emission color. That is, the light-emitting elements 30 are uniformly arranged on a surface on one side of the array substrate 10. In this embodiment, there is no specific requirement or special limitation on the arrangement order of light-emitting elements 30 having different emission colors in a corresponding pixel unit 40. In an actual application process, those skilled in the art may select and set the arrangement of the light-emitting element 30 according to an actual need. The limitation of the emission color of the light-emitting element 30 is not specifically described in FIG. 1 and subsequent embodiments. In addition, the number of light-emitting elements 30 in the drawing of the embodiment of the present disclosure is only an example and does not represent an actual situation.

It is also to be noted that adjacent pixel units 40 arranged in 3×1 are used as an example for description in the subsequent embodiments. The pixel units 40 include three light-emitting elements 30 sequentially arranged in the first direction X. Emission colors of these three light-emitting elements 30 may be the same or different and are not specifically limited. In different pixel units 40, three light-emitting elements 30 sequentially arranged in the second direction Y have the same emission color. The first direction X may also be understood as a direction in which at least two types of light-emitting elements 30 having different colors are sequentially arranged, the second direction Y may also be understood as a direction in which light-emitting elements 30 having the same color are sequentially arranged, and the first direction X and the second direction Y are parallel to the array substrate 10 and intersect with each other.

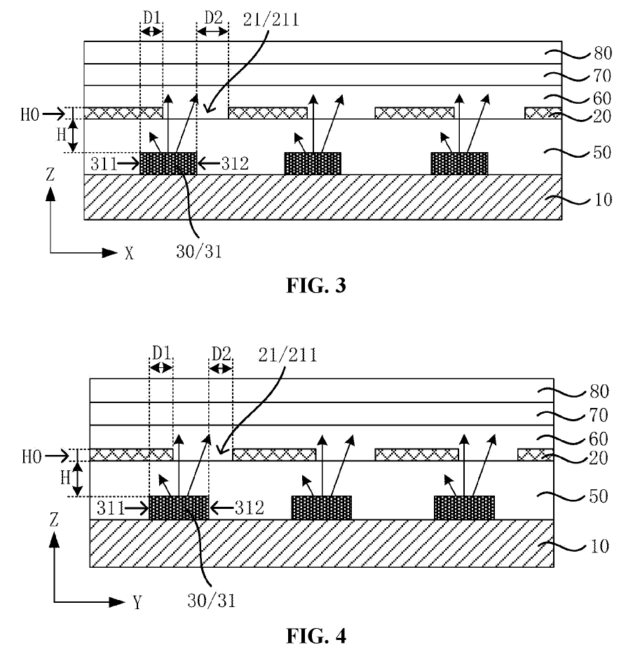

FIG. 2 is a top view of a display panel according to an embodiment of the present disclosure. FIG. 3 is a section view taken along a section line AA' of the display panel of FIG. 2. As shown in FIGS. 2 and 3, the display panel includes an array substrate 10, a light-shielding layer 20 and multiple light-emitting elements 30. The light-shielding layer 20 is located on one side of the light-emitting elements 30 facing away from the array substrate 10, and the light-shielding layer 20 includes multiple openings 21. In a thickness direction of the display panel, the openings 21 at least partially overlap the light-emitting elements 30 in one-to-one correspondence, and a center of the light-emitting element 30 overlaps the opening 21 and does not overlap the light-shielding layer 20.

The thickness direction of the display panel may be understood as a third direction Z. Specifically, the light-shielding layer 20 is located on the one side of the light-emitting elements 30 facing away from the array substrate 10. For example, the light-shielding layer 20 may consist of a material which is a transparent adhesive material doped with carbon black light-absorbing particles, or may also consist of a black adhesive material in a dissolved form. The light-shielding layer 20 includes the multiple openings 21. For example, the number of openings 21 is the same as the number of light-emitting elements 30, and in the third direction Z, the openings 20 of the light-shielding layer 20 at least partially overlap the light-emitting elements 30 in one-to-one correspondence. In other words, an orthographic projection of the opening 21 of the light-shielding layer 20 on the surface of the array substrate 10 at least partially overlaps an orthographic projection of a corresponding light-emitting element 30 on the surface of the array substrate 10. That is, in the display panel, the light-shielding layer 20 with the openings 21 is disposed at a light emission side of the light-emitting elements 30. The light-shielding layer 20 can effectively adjust an angle of light emitted from the light-emitting element 30 to meet different requirements for light emission. For example, the wide-angle beams from the light-emitting element 30 are shielded, thereby avoiding the problem that this type of wide-angle beams are easily reflected by other objects after emission, enters the human eyes to form a reflection and generate a virtual image and interfere with the user's line of sight, and ensuring the user's undisturbed field of view for observation of an external environment of the display panel. For example, the openings 21 of the light-shielding layer 20 may be prepared through a photolithography technique. In a more understandable manner, the light-shielding layer 10 may cover the entire side of the light-emitting elements 30 facing away from the array substrate 10, and the openings 21 are formed in upper regions corresponding to the light-emitting elements 30 through the photolithography technique.

Moreover, the center of the light-emitting element 30 overlaps a corresponding opening 21 and does not overlap the light-shielding layer 20. The positional relationships of the center of the light-emitting element 30 relative to the corresponding opening 21 and the light-shielding layer 20 are set, and the opening 21 can ensure the emission of on-axis beams from the center of the light-emitting element 30 or the emission of narrow-angle beams from a position close to the center of the light-emitting element 30. This portion of emitted light is not shielded by the light-shielding layer 20. In this manner, an amount of on-axis beams emitted from the light-emitting element 30 is ensured, and when the user views the display panel at a frontal or approximately frontal viewing angle, the display panel is in a normal display state, ensuring the user's good viewing experience of the display panel. It may be understood that since the light emitted from the micro-LED display panel has a divergent pattern, the brightness of wide-angle beams is equivalent to or even higher than the brightness of on-axis beams. Therefore, the brightness of the viewing angle of the display panel is not significantly reduced by the positional relationships of the center of the light-emitting element 30 relative to the corresponding opening 21 and the light-shielding layer 20. In addition, the center of the light-emitting element 30 and a subsequent center of the opening 21 in this embodiment may be understood as geometric centers. Shapes or sizes of the light-emitting element 30 and the opening 21 may be set according to actual needs, and only the orthographic projection being rectangular is used for drawing and description here.

The light-shielding layer 20 can effectively adjust the angle of the light emitted from the light-emitting element 30, for example, the wide-angle beams from the light-emitting element 30 are shielded. The opening 21 can ensure the emission of the on-axis beams from the center of the light-emitting element 30 or the emission of the narrow-angle beams from the position close to the center of the light-emitting element 30. In this manner, reasonably setting the shielding degree or shielding position of the light-shielding layer 20 to the light-emitting element 30 can meet a requirement of a particular side of the display panel for shielding wide-angle beams and ensure a viewing effect of normal display on other sides. This can satisfy some particular application scenarios, for example, an in-vehicle display screen (including, but not limited to, an in-vehicle instrument screen and a central control display screen) scenario. When the display panel is applied to in-vehicle display, a particular side of the in-vehicle display screen may be an upper side of the screen (the upper side of the screen may also be understood as a positive direction of the second direction Y shown in FIG. 3), and the light-shielding layer 20 can shield wide-angle beams corresponding to the upper side of the screen, thereby solving the problem that the wide-angle beams emitted from the upper side of the in-vehicle display screen are easily reflected by the front windshield or the side window glass to form a ghost image which affects the driver's line of sight, ensuring that the driver has a good line of sight in the vehicle and can see the scene outside the vehicle, and ensuring driver's driving safety. Moreover, a particular side of the in-vehicle display screen may be a left side of the screen (the left side of the screen may also be understood as a negative direction of the first direction X shown in FIG. 3), and the light-shielding layer 20 can shield wide-angle beams corresponding to the left side of the screen, thereby solving the problem that the wide-angle beams emitted from the left side of the in-vehicle display screen are easily reflected by the front windshield or the side window glass to form a ghost image which affects the driver's line of sight, ensuring that the driver has a good line of sight in the vehicle and can see the scene outside the vehicle, and ensuring driver's driving safety. That is, on the particular side of the in-vehicle display screen that needs to shield wide-angle beams, for example, in a direction corresponding to the front windshield or the side window glass. Wide-angle beams emitted from a corresponding light-emitting element 30 can be shielded by the light-shielding layer 20 to reduce or even avoid the formation of a ghost image in the direction corresponding to the front windshield or the side window glass. Moreover, on other sides of the in-vehicle display screen that the user needs to view, for example, in a direction corresponding to the driver's seat (which may be understood as a lower side of the screen or a negative direction of the second direction Y shown in FIG. 3, and is opposite to the upper side of the screen) or front passenger seat (which may be understood as a right side of the screen or a positive direction of the first direction X shown in FIG. 3, and is opposite to the left side of the screen) of the vehicle, the light-shielding layer 20 does not shield light emitted from a corresponding light-emitting element 30, and the light emitted from the light-emitting element 30 can be emitted from a corresponding opening 21. For example, wide-angle beams emitted from the light-emitting element 30 can be emitted to the direction corresponding to the driver's seat or the front passenger seat to enhance the brightness for viewing the screen in this direction, thereby ensuring a normal viewing requirement of the driver's seat or the front passenger seat for the in-vehicle display screen.

It is also to be noted that the structural design of the display panel in this embodiment may be applied to a transparent display screen and a non-transparent display screen. In the transparent display screen, the array substrate 10 and the multiple light-emitting elements 30 may be designed to be transparent, and the light-shielding layer 20 may be designed to be hollow. In the non-transparent display screen, materials of the array substrate 10, the light-shielding layer 20 and the multiple light-emitting elements 30 may be selected and set according to actual needs.

The display panel includes the multiple light-emitting elements 30, and the light-shielding layer 20 includes the multiple openings 21. For example, the number of openings 21 is the same as the number of light-emitting elements 30, and the openings 21 and the light-emitting elements 30 are disposed in one-to-one correspondence. The opening 21 at least partially overlaps the light-emitting element 30 in the thickness direction of the display panel. The openings 21 include first openings 211, and the light-emitting elements 30 include first light-emitting elements 31. In this embodiment, a corresponding first opening 211 and first light-emitting element 31 in one group are essentially used for an example for description, the positional relationships between corresponding first openings 211 and first light-emitting elements 31 in other groups may be the same or different, and this is not limited here. On this basis, a specific positional relationship between the first opening 211 and the first light-emitting element 31 is described below by using an example.

In an embodiment, optionally, with continued reference to FIGS. 2 and 3, the openings 21 include first openings 211, and the light-emitting elements 30 include first light-emitting elements 31. In the thickness direction of the display panel, a first light-emitting element 31 partially overlaps a first opening 211, and a center O1 of the first light-emitting element 31 does not overlap a center O2 of the first opening 211.

The thickness direction of the display panel may be understood as the third direction Z. Specifically, in the third direction Z, the first light-emitting element 31 corresponds to the first opening 211, and the first light-emitting element 31 partially overlaps the first opening 211, that is, a portion of an orthographic projection of the first light-emitting element 31 on the surface of the array substrate 10 overlaps an orthographic projection of the first opening 211 on the surface of the array substrate 10. Moreover, the center O1 of the first light-emitting element 31 does not overlap the center O2 of the first opening 211, that is, an orthographic projection of the center O1 of the first light-emitting element 31 on the surface of the array substrate 10 is misaligned with an orthographic projection of the center O2 of the first opening 211 on the surface of the array substrate 10 so that the pattern of the light emitted from the first light-emitting element 31 can be asymmetric and the asymmetric light pattern is generated, thereby achieving the adjustment from the divergent light pattern to the asymmetric light pattern and achieving the modulation of the flattening and non-centrosymmetry of the light pattern. In this manner, it is possible to make the light-shielding layer 20 shield wide-angle beams emitted from the first light-emitting element 31 on two sides in a misalignment direction to different degrees, that is, the requirement of the particular side of the display panel for shielding the wide-angle beams is met.

Optionally, with continued reference to FIGS. 2 and 3, in the thickness direction of the display panel, at least a portion of the first light-emitting element 31 overlaps the light-shielding layer 20.

The thickness direction of the display panel may be understood as the third direction Z. Specifically, in the third direction Z, a portion of the first light-emitting element 31 overlaps the light-shielding layer 20, that is, a portion of the orthographic projection of the first light-emitting element 31 on the surface of the array substrate 10 overlaps an orthographic projection of the light-shielding layer 20 on the surface of the array substrate 10. In this manner, the light-shielding layer 20 can effectively shield wide-angle beams emitted from the first light-emitting element 31 corresponding to this overlap region, thereby meeting the requirement of the particular side of the display panel for shielding the wide-angle beams.

Optionally, with continued reference to FIGS. 2 and 3, in the thickness direction of the display panel, the center O1 of the first light-emitting element 31 does not overlap the light-shielding layer 20.

The thickness direction of the display panel may be understood as the third direction Z. Specifically, in the third direction Z, the center O1 of the first light-emitting element 31 does not overlap the light-shielding layer 20, that is, the orthographic projection of the center O1 of the first light-emitting element 31 on the surface of the array substrate 10 does not overlap the orthographic projection of the light-shielding layer 20 on the surface of the array substrate 10. In this manner, the light-shielding layer 20 does not shield on-axis beams or narrow-angle beams emitted from the first light-emitting element 31, thereby ensuring an amount of on-axis beams emitted from the first light-emitting element 30. When the user views the display panel at a frontal or approximately frontal viewing angle, the display panel is in the normal display state, ensuring the user's good viewing experience of the display panel.

Optionally, with continued reference to FIGS. 2 and 3, the multiple light-emitting elements 30 include at least two types of light-emitting elements 30 having different colors, and the at least two types of light-emitting elements 30 are arranged along a first direction X; for a first side and a second side of the first light-emitting element 31 that face away from each other in the first direction X, a partial structure at the first side overlaps the light-shielding layer 20 along the thickness direction of the display panel, and a partial structure at the second side does not overlap the light-shielding layer 20 in the thickness direction of the display panel.

The first direction X may be understood as a direction in which at least two types of light-emitting elements 30 having different colors are sequentially arranged, and the thickness direction of the display panel may be understood as the third direction Z. For example, the multiple light-emitting elements 30 may include, but are not limited to, red light-emitting elements, green light-emitting elements, blue light-emitting elements and white light-emitting elements. Specifically, the partial structure at the first side of the first light-emitting element 31 in the first direction X overlaps the light-shielding layer 20 in the third direction Z, that is, wide-angle beams correspondingly emitted from the partial structure at the first side of the first light-emitting element 31 in the first direction X are shielded by the light-shielding layer 20 and cannot be emitted. Moreover, the partial structure at the second side of the first light-emitting element 31 in the first direction X does not overlap the light-shielding layer 20 in the third direction Z, that is, wide-angle beams correspondingly emitted from the partial structure at the second side of the first light-emitting element 31 in the first direction X are not shielded by the light-shielding layer 20 and can be emitted normally. In this manner, shielding degrees of the light-shielding layer 20 to the partial structures at the first side and the second side of the first light-emitting element 31 that face away from each other in the first direction X are different, thereby meeting the requirement of the particular side of the display panel for shielding the wide-angle beams.

For example, the first light-emitting element 31 shown in FIG. 3 is used as an example for description. In the first direction X, the wide-angle beams corresponding to the partial structure at the first side of the first light-emitting element 31 (which may be understood as a partial structure at a left side of the first light-emitting element 31 or a partial structure of the first light-emitting element 31 facing the negative direction of the first direction X) are shielded by the light-shielding layer 20 and cannot be emitted; the wide-angle beams corresponding to the partial structure at the second side of the first light-emitting element 31 (which may be understood as a partial structure at a right side of the first light-emitting element 31 or a partial structure of the first light-emitting element 31 facing the positive direction of the first direction X) are not shielded by the light-shielding layer 20 and can be emitted normally; on-axis beams or narrow-angle beams from the middle of the first light-emitting element 31 is also not shielded by the light-shielding layer 20 and can be emitted normally. The above description can satisfy some particular application scenarios, for example, an in-vehicle display screen (including, but not limited to, an in-vehicle instrument screen and a central control display screen) scenario. When the display panel is applied to in-vehicle display, a particular side of the in-vehicle display screen may be a left side of the screen, and the light-shielding layer 20 can shield wide-angle beams corresponding to the left side of the screen, thereby solving the problem that the wide-angle beams emitted from the left side of the in-vehicle display screen are easily reflected by the front windshield or the side window glass to form a ghost image which affects the driver's line of sight, ensuring that the driver has a good line of sight in the vehicle and can see the scene outside the vehicle, and ensuring driver's driving safety.

On this basis, further, FIG. 4 is a section view taken along a section line BB' of the display panel of FIG. 2. As shown in FIGS. 2 and 4, for a first side and a second side of the first light-emitting element 31 that face away from each other along a second direction Y, a partial structure at the first side overlaps the light-shielding layer 20 in the thickness direction of the display panel, and a partial structure at the second side does not overlap the light-shielding layer 20 in the thickness direction of the display panel, where the first direction X and the second direction Y are parallel to the array substrate 10 and intersect with each other.

Specifically, the partial structure at the first side of the first light-emitting element 31 in the second direction Y overlaps the light-shielding layer 20 in the third direction Z, that is, wide-angle beams correspondingly emitted from the partial structure at the first side of the first light-emitting element 31 in the second direction Y are shielded by the light-shielding layer 20 and cannot be emitted. Moreover, the partial structure at the second side of the first light-emitting element 31 in the second direction Y does not overlap the light-shielding layer 20 in the third direction Z, that is, wide-angle beams correspondingly emitted from the partial structure at the second side of the first light-emitting element 31 in the second direction Y are not shielded by the light-shielding layer 20 and can be emitted normally. In this manner, shielding degrees of the light-shielding layer 20 to the partial structures at the first side and the second side of the first light-emitting element 31 that face away from each other in the second direction Y are different, thereby meeting the requirement of the particular side of the display panel for shielding the wide-angle beams.

For example, the first light-emitting element 31 shown in FIG. 4 is used as an example for description. In the second direction Y, the wide-angle beams corresponding to the partial structure at the first side of the first light-emitting element 31 (which may be understood as a partial structure at an upper side of the first light-emitting element 31 or a partial structure of the first light-emitting element 31 facing the positive direction of the second direction Y) are shielded by the light-shielding layer 20 and cannot be emitted; the wide-angle beams corresponding to the partial structure at the second side of the first light-emitting element 31 (which may be understood as a partial structure at a lower side of the first light-emitting element 31 or a partial structure of the first light-emitting element 31 facing the negative direction of the second direction Y) are not shielded by the light-shielding layer 20 and can be emitted normally; on-axis beams or narrow-angle beams from the middle of the first light-emitting element 31 is also not shielded by the light-shielding layer 20 and can be emitted normally. The above description can satisfy some particular application scenarios, for example, an in-vehicle display screen (including, but not limited to, an in-vehicle instrument screen and a central control display screen) scenario. When the display panel is applied to in-vehicle display, a particular side of the in-vehicle display screen may be an upper side of the screen, and the light-shielding layer 20 can shield wide-angle beams corresponding to the upper side of the screen, thereby solving the problem that the wide-angle beams emitted from the upper side of the in-vehicle display screen are easily reflected by the front windshield or the side window glass to form a ghost image which affects the driver's line of sight, ensuring that the driver has a good line of sight in the vehicle and can see the scene outside the vehicle, and ensuring driver's driving safety.

On this basis, further, with continued reference to FIGS. 2, 3 and 4, spacing between the second side of the first light-emitting element 31 in the first direction X and an edge of the first opening 211 is not equal to spacing between the second side of the first light-emitting element 31 in the second direction Y and an edge of the first opening 211.

Specifically, the partial structure at the second side of the first light-emitting element 31 in the first direction X does not overlap the light-shielding layer 20 in the third direction Z, that is, the wide-angle beams correspondingly emitted from the partial structure at the second side of the first light-emitting element 31 in the first direction X are not shielded by the light-shielding layer 20 and can be emitted normally. The spacing between the second side of the first light-emitting element 31 in the first direction X and the edge of the first opening 211 affects an amount of wide-angle beams correspondingly emitted from the first light-emitting element 31 in the first direction X. The edge spacing described in this embodiment here may be understood as spacing between the second side of the first light-emitting element 31 in the first direction X and an edge of the first opening 211 facing the second side of the first light-emitting element 31 in the first direction X, or may be understood as spacing between the second side of the first light-emitting element 31 in the first direction X and an edge of the first opening 211 facing the first side of the first light-emitting element 31 in the first direction X. Moreover, the partial structure at the second side of the first light-emitting element 31 in the second direction Y does not overlap the light-shielding layer 20 in the third direction Z, that is, the wide-angle beams correspondingly emitted from the partial structure at the second side of the first light-emitting element 31 in the second direction Y are not shielded by the light-shielding layer 20 and can be emitted normally. The spacing between the second side of the first light-emitting element 31 in the second direction Y and the edge of the first opening 211 affects an amount of wide-angle beams correspondingly emitted from the first light-emitting element 31 in the second direction Y. The edge spacing described in this embodiment here may be understood as spacing between the second side of the first light-emitting element 31 in the second direction Y and an edge of the first opening 211 facing the second side of the first light-emitting element 31 in the second direction Y, or may be understood as spacing between the second side of the first light-emitting element 31 in the second direction Y and an edge of the first opening 211 facing the first side of the first light-emitting element 31 in the second direction Y.

This embodiment defines that these two edge spacing values are unequal here. Therefore, an amount of wide-angle beams correspondingly emitted from the second side of the first light-emitting element 31 in the first direction X is different from an amount of wide-angle beams correspondingly emitted from the second side of the first light-emitting element 31 in the second direction Y, and a total amount of light correspondingly emitted from the first light-emitting element 31 in the first direction X is also different from a total amount of light correspondingly emitted from the first light-emitting element 31 in the second direction Y, thereby meeting requirements for light emission at different angles or different positions. That is, more requirements of the first light-emitting element 31 for the adjustment from the divergent light pattern to the asymmetric light pattern are met, and the requirement of the particular side of the display panel for shielding the wide-angle beams can also be met. For example, the spacing between the second side of the first light-emitting element 31 in the first direction X and the edge of the first opening 211 may be greater than the spacing between the second side of the first light-emitting element 31 in the second direction Y and the edge of the first opening 211. The above description can satisfy some particular application scenarios, for example, an in-vehicle display screen (including, but not limited to, an in-vehicle instrument screen and a central control display screen) scenario. When the display panel is applied to in-vehicle display, a particular side of the in-vehicle display screen may be a left side of the screen (which may be understood as the first side of the first light-emitting element 31 in the first direction X) and an upper side of the screen (which may be understood as the first side of the first light-emitting element 31 in the second direction Y). In this case, an amount of wide-angle beams correspondingly emitted from a right side of the screen (which may be understood as the second side of the first light-emitting element 31 in the first direction X or a front passenger seat) may be greater than an amount of wide-angle beams correspondingly emitted from a lower side of the screen (which may be understood as the second side of the first light-emitting element 31 in the second direction Y or a driver's seat), ensuring that the driver has a good line of sight in the vehicle. Moreover, to ensure the driving safety of the driver on the driver's seat of the vehicle and in consideration of viewing the screen of the display panel from the front passenger seat of the vehicle, the front passenger seat can allow more wide-angle beams emitted from the display panel.

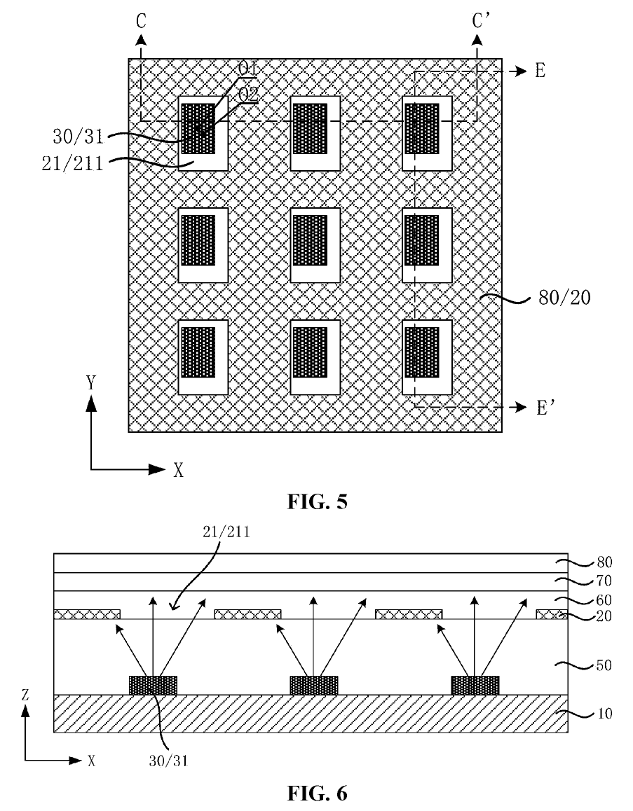

In another embodiment, optionally, FIG. 5 is a top view of another display panel according to an embodiment of the present disclosure, and FIG. 6 is a section view taken along a section line CC' of the display panel of FIG. 5. As shown in FIGS. 5 and 6, the openings 21 include first openings 211, and the light-emitting elements 30 include first light-emitting elements 31; in the thickness direction of the display panel, a first light-emitting element 31 completely overlaps a first opening 211, and a center O1 of the first light-emitting element 31 does not overlap a center O2 of the first opening 211.

The thickness direction of the display panel may be understood as a third direction Z. Specifically, in the third direction Z, the first light-emitting element 31 corresponds to the first opening 211, and the first light-emitting element 31 completely overlaps the first opening 211, that is, an entire orthographic projection of the first light-emitting element 31 on the surface of the array substrate 10 is located within an orthographic projection of the first opening 211 on the surface of the array substrate 10. Moreover, the center O1 of the first light-emitting element 31 does not overlap the center O2 of the first opening 211, that is, an orthographic projection of the center O1 of the first light-emitting element 31 on the surface of the array substrate 10 is misaligned with an orthographic projection of the center O2 of the first opening 211 on the surface of the array substrate 10 so that a light pattern of light emission of the first light-emitting element 31 can be asymmetric and the asymmetric light pattern is generated, thereby achieving the adjustment from the divergent light pattern to the asymmetric light pattern and achieving the modulation of the flattening and non-centrosymmetry of the light pattern. In this manner, it is possible to make the light-shielding layer 20 shield wide-angle beams emitted from the first light-emitting element 31 on two sides in a misalignment direction to different degrees, that is, the requirement of the particular side of the display panel for shielding the wide-angle beams is met.

Optionally, with continued reference to FIGS. 5 and 6, in the thickness direction of the display panel, the first light-emitting element 31 does not overlap the light-shielding layer 20.

The thickness direction of the display panel may be understood as the third direction Z. Specifically, in the third direction Z, the first light-emitting element 31 does not overlap the light-shielding layer 20, that is, the entire orthographic projection of the first light-emitting element 31 on the surface of the array substrate 10 does not overlap an orthographic projection of the light-shielding layer 20 on the surface of the array substrate 10. To achieve an effect of shielding wide-angle beams emitted from the first light-emitting element 31 by the light-shielding layer 20 shown in FIG. 6, a distance between the light-shielding layer 20 and the first light-emitting element 31 in the third direction Z may be appropriately increased and may be reasonably set according to positional relationships between the light-shielding layer 20 and other film structures, thereby meeting the requirement of the particular side of the display panel for shielding the wide-angle beams.

Optionally, with continued reference to FIGS. 5 and 6, the multiple light-emitting elements 30 include at least two types of light-emitting elements 30 having different colors, and the at least two types of light-emitting elements 30 are arranged along a first direction X; for a first side and a second side of the first light-emitting element 31 that face away from each other along the first direction X, edge spacing between the first light-emitting element 31 and the first opening 211 at the first side along the first direction X is less than edge spacing between the first light-emitting element 31 and the first opening 211 at the second side along the first direction X.

The first direction X may be understood as a direction in which at least two types of light-emitting elements 30 having different colors are arranged sequentially. For example, the multiple light-emitting elements 30 may include, but are not limited to, red light-emitting elements, green light-emitting elements, blue light-emitting elements and white light-emitting elements. Specifically, the edge spacing between the first light-emitting element 31 and the first opening 211 at the first side along the first direction X may be understood as spacing between the first side of the first light-emitting element 31 in the first direction X and an edge of a corresponding first opening 211 facing the first side of the first light-emitting element 31 in the first direction X, and the edge spacing between the first light-emitting element 31 and the first opening 211 at the second side along the first direction X may be understood as spacing between the second side of the first light-emitting element 31 in the first direction X and an edge of the corresponding first opening 211 facing the second side of the first light-emitting element 31 in the first direction X. Here, this embodiment defines that these two edge spacing values are unequal, and the edge spacing between the first light-emitting element 31 and the first opening 211 at the first side along the first direction X is less than the edge spacing between the first light-emitting element 31 and the first opening 211 at the second side along the first direction X. Therefore, wide-angle beams correspondingly emitted from a partial structure at the first side of the first light-emitting element 31 in the first direction X are more shielded by the light-shielding layer 20 and cannot be emitted, and wide-angle beams correspondingly emitted from a partial structure at the second side of the first light-emitting element 31 in the first direction X is less shielded by the light-shielding layer 20 and cannot be emitted. That is, an amount of the wide-angle beams correspondingly emitted from the first side of the first light-emitting element 31 in the first direction X is less than an amount of the wide-angle beams correspondingly emitted from the second side of the first light-emitting element 31 in the first direction X, and shielding degrees of the light-shielding layer 20 to the wide-angle beams on the first side and the second side of the first light-emitting element 31 in the first direction X are different. The light-shielding layer 20 effectively shields the wide-angle beams correspondingly emitted from the first side of the first light-emitting element 31 in the first direction X, thereby meeting the requirement of the particular side of the display panel for shielding the wide-angle beams.

For example, the first light-emitting element 31 shown in FIG. 6 is used as an example for description. In the first direction X, the wide-angle beams corresponding to the partial structure at the first side of the first light-emitting element 31 (which may be understood as a partial structure at a left side of the first light-emitting element 31 or a partial structure of the first light-emitting element 31 facing a negative direction of the first direction X) are more shielded by the light-shielding layer 20; the wide-angle beams corresponding to the partial structure at the second side of the first light-emitting element 31 (which may be understood as a partial structure at a right side of the first light-emitting element 31 or a partial structure of the first light-emitting element 31 facing a positive direction of the first direction X) is less shielded by the light-shielding layer 20; on-axis beams or narrow-angle beams from the middle of the first light-emitting element 31 are not shielded by the light-shielding layer 20 and can be emitted normally. The above description can satisfy some particular application scenarios, for example, an in-vehicle display screen (including, but not limited to, an in-vehicle instrument screen and a central control display screen) scenario. When the display panel is applied to in-vehicle display, a particular side of the in-vehicle display screen may be a left side of the screen, and the light-shielding layer 20 can shield wide-angle beams corresponding to the left side of the screen to a great extent, thereby solving the problem that the wide-angle beams emitted from the left side of the in-vehicle display screen are easily reflected by the front windshield or the side window glass to form a ghost image which affects the driver's line of sight, ensuring that the driver has a good line of sight in the vehicle and can see the scene outside the vehicle, and ensuring driver's driving safety.

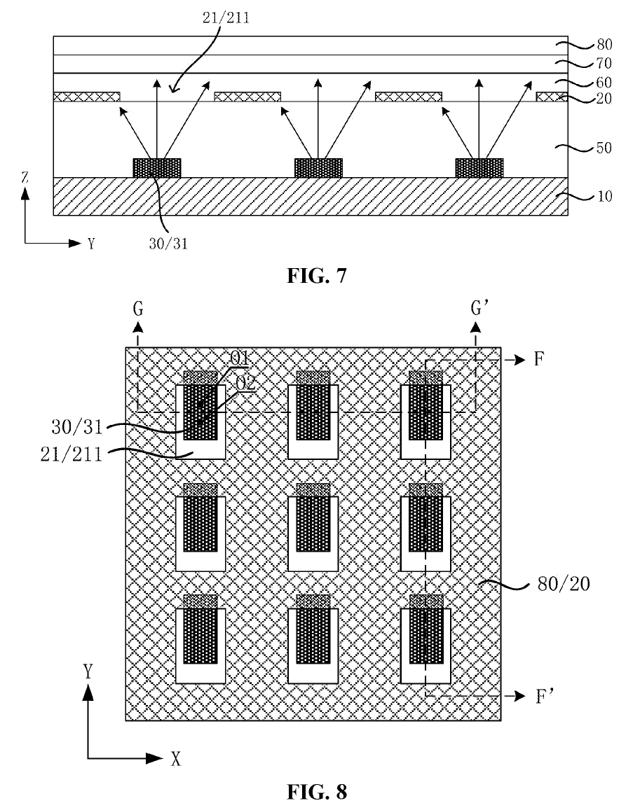

Optionally, FIG. 7 is a section view taken along a section line EE' of the display panel of FIG. 5. As shown in FIGS. 5 and 7, for a first side and a second side of the first light-emitting element 31 that face away from each other along a second direction Y, edge spacing between the first light-emitting element 31 and the first opening 211 at the first side along the second direction Y is less than edge spacing between the first light-emitting element 31 and the first opening 211 at the second side along the second direction Y, where the first direction X and the second direction Y are parallel to the array substrate 10 and intersect with each other.

Specifically, the edge spacing between the first light-emitting element 31 and the first opening 211 at the first side along the second direction Y may be understood as spacing between the first side of the first light-emitting element 31 in the second direction Y and an edge of a corresponding first opening 211 facing the first side of the first light-emitting element 31 in the second direction Y, and the edge spacing between the first light-emitting element 31 and the first opening 211 at the second side along the second direction Y may be understood as spacing between the second side of the first light-emitting element 31 in the second direction Y and an edge of the corresponding first opening 211 facing the second side of the first light-emitting element 31 in the second direction Y. Here, this embodiment defines that these two edge spacing values are unequal, and the edge spacing between the first light-emitting element 31 and the first opening 211 at the first side along the second direction Y is less than the edge spacing between the first light-emitting element 31 and the first opening 211 at the second side along the second direction Y. Therefore, wide-angle beams correspondingly emitted from a partial structure at the first side of the first light-emitting element 31 in the second direction Y are more shielded by the light-shielding layer 20 and cannot be emitted, and wide-angle beams correspondingly emitted from a partial structure at the second side of the first light-emitting element 31 in the second direction Y is less shielded by the light-shielding layer 20 and cannot be emitted. That is, an amount of the wide-angle beams correspondingly emitted from the first side of the first light-emitting element 31 in the second direction Y is less than an amount of the wide-angle beams correspondingly emitted from the second side of the first light-emitting element 31 in the second direction Y, and shielding degrees of the light-shielding layer 20 to the wide-angle beams on the first side and the second side of the first light-emitting element 31 in the second direction Y are different. The light-shielding layer 20 effectively shields the wide-angle beams correspondingly emitted from the first side of the first light-emitting element 31 in the second direction Y, thereby meeting the requirement of the particular side of the display panel for shielding the wide-angle beams.

For example, the first light-emitting element 31 shown in FIG. 7 is used as an example for description. In the second direction Y, the wide-angle beams corresponding to the partial structure at the first side of the first light-emitting element 31 (which may be understood as a partial structure at an upper side of the first light-emitting element 31 or a partial structure of the first light-emitting element 31 facing a positive direction of the second direction Y) are more shielded by the light-shielding layer 20; the wide-angle beams corresponding to the partial structure at the second side of the first light-emitting element 31 (which may be understood as a partial structure at a lower side of the first light-emitting element 31 or a partial structure of the first light-emitting element 31 facing a negative direction of the second direction Y) is less shielded by the light-shielding layer 20; on-axis beams or narrow-angle beams from the middle of the first light-emitting element 31 are not shielded by the light-shielding layer 20 and can be emitted normally. The above description can satisfy some particular application scenarios, for example, an in-vehicle display screen (including, but not limited to, an in-vehicle instrument screen and a central control display screen) scenario. When the display panel is applied to in-vehicle display, a particular side of the in-vehicle display screen may be an upper side of the screen, and the light-shielding layer 20 can shield wide-angle beams corresponding to the upper side of the screen to a great extent, thereby solving the problem that the wide-angle beams emitted from the upper side of the in-vehicle display screen are easily reflected by the front windshield or the side window glass to form a ghost image which affects the driver's line of sight, ensuring that the driver has a good line of sight in the vehicle and can see the scene outside the vehicle, and ensuring driver's driving safety.

On this basis, for example, the edge spacing between the first light-emitting element 31 and the first opening 211 at the first side in the first direction X is not equal to the edge spacing between the first light-emitting element 31 and the first opening 211 at the first side in the second direction Y. In this case, it does not matter whether the edge spacing between the first light-emitting element 31 and the first opening 211 at the second side in the first direction X is equal to the edge spacing between the first light-emitting element 31 and the first opening 211 at the second side in the second direction Y.

Specifically, this embodiment defines that the edge spacing between the first light-emitting element 31 and the first opening 211 at the first side in the first direction X is not equal to the edge spacing between the first light-emitting element 31 and the first opening 211 at the first side in the second direction Y here. Therefore, an amount of wide-angle beams correspondingly emitted from the first side of the first light-emitting element 31 in the first direction X is different from an amount of wide-angle beams correspondingly emitted from the first side of the first light-emitting element 31 in the second direction Y, that is, the light-shielding layer 20 has different effects of shielding the wide-angle beams corresponding to the first side of the first light-emitting element 31 in the first direction X and the wide-angle beams corresponding to the first side of the first light-emitting element 31 in the second direction Y, thereby meeting requirements for light emission at different angles or different positions. Moreover, the requirement of the particular side of the display panel for shielding the wide-angle beams can also be met. In this case, the edge spacing between the first light-emitting element 31 and the first opening 211 at the second side in the first direction X may be equal to or may not be equal to the edge spacing between the first light-emitting element 31 and the first opening 211 at the second side in the second direction Y, which may be reasonably set according to the requirement for light emission. No more examples are given in this embodiment.

Alternatively, for example, the edge spacing between the first light-emitting element 31 and the first opening 211 at the second side in the first direction X is not equal to the edge spacing between the first light-emitting element 31 and the first opening 211 at the second side in the second direction Y. In this case, it does not matter whether the edge spacing between the first light-emitting element 31 and the first opening 211 at the first side in the first direction X is equal to the edge spacing between the first light-emitting element 31 and the first opening 211 at the first side in the second direction Y.

Specifically, this embodiment defines that the edge spacing between the first light-emitting element 31 and the first opening 211 at the second side in the first direction X is not equal to the edge spacing between the first light-emitting element 31 and the first opening 211 at the second side in the second direction Y here. Therefore, an amount of wide-angle beams correspondingly emitted from the second side of the first light-emitting element 31 in the first direction X is different from an amount of wide-angle beams correspondingly emitted from the second side of the first light-emitting element 31 in the second direction Y, that is, the light-shielding layer 20 has different effects of shielding the wide-angle beams corresponding to the second side of the first light-emitting element 31 in the first direction X and the wide-angle beams corresponding to the second side of the first light-emitting element 31 in the second direction Y, thereby meeting requirements for light emission at different angles or different positions. Moreover, the requirement of the particular side of the display panel for shielding the wide-angle beams can also be met. In this case, the edge spacing between the first light-emitting element 31 and the first opening 211 at the first side in the first direction X may be equal to or may not be equal to the edge spacing between the first light-emitting element 31 and the first opening 211 at the first side in the second direction Y, which may be reasonably set according to the requirement for light emission. No more examples are given in this embodiment.

Further, with continued reference to FIGS. 5, 6 and 7, the edge spacing between the first light-emitting element 31 and the first opening 211 at the first side in the first direction X is not equal to the edge spacing between the first light-emitting element 31 and the first opening 211 at the first side in the second direction Y, and the edge spacing between the first light-emitting element 31 and the first opening 211 at the second side in the first direction X is not equal to the edge spacing between the first light-emitting element 31 and the first opening 211 at the second side in the second direction Y.

Specifically, this embodiment defines that the edge spacing between the first light-emitting element 31 and the first opening 211 at the first side in the first direction X is not equal to the edge spacing between the first light-emitting element 31 and the first opening 211 at the first side in the second direction Y, and the edge spacing between the first light-emitting element 31 and the first opening 211 at the second side in the first direction X is not equal to the edge spacing between the first light-emitting element 31 and the first opening 211 at the second side in the second direction Y here. Therefore, an amount of wide-angle beams correspondingly emitted from the first side of the first light-emitting element 31 in the first direction X is different from an amount of wide-angle beams correspondingly emitted from the first side of the first light-emitting element 31 in the second direction Y, and an amount of wide-angle beams correspondingly emitted from the second side of the first light-emitting element 31 in the first direction X is different from an amount of wide-angle beams correspondingly emitted from the second side of the first light-emitting element 31 in the second direction Y. The light-shielding layer 20 has different effects of shielding the wide-angle beams corresponding to the sides of the first light-emitting element 31, thereby further meeting requirements for light emission at different angles or different positions, achieving the adjustment from the divergent light pattern to the asymmetric light pattern and achieving the modulation of the flattening and non-centrosymmetry of the light pattern. Moreover, the requirement of the particular side of the display panel for shielding the wide-angle beams can also be met. For example, the edge spacing between the first light-emitting element 31 and the first opening 211 at the first side in the first direction X may be less than the edge spacing between the first light-emitting element 31 and the first opening 211 at the first side in the second direction Y, and the edge spacing between the first light-emitting element 31 and the first opening 211 at the second side in the first direction X may be greater than the edge spacing between the first light-emitting element 31 and the first opening 211 at the second side in the second direction Y. The above description can satisfy some particular application scenarios, for example, an in-vehicle display screen (including, but not limited to, an in-vehicle instrument screen and a central control display screen) scenario. When the display panel is applied to in-vehicle display, particular sides of the in-vehicle display screen may be a left side of the screen (which may be understood as the first side of the first light-emitting element 31 in the first direction X) and an upper side of the screen (which may be understood as the first side of the first light-emitting element 31 in the second direction Y). The light-shielding layer 20 can shield wide-angle beams corresponding to the left side of the screen and wide-angle beams corresponding to the upper side of the screen, and a shielding degree of the light-shielding layer 20 to the wide-angle beams corresponding to the upper side of the screen may be greater than a shielding degree of the light-shielding layer 20 to the wide-angle beams corresponding to the left side of the screen. The reason is that the front windshield of the vehicle has an inclination angle and the wide-angle beams correspondingly emitted from the first light-emitting element 31 are more easily reflected by the front windshield. Therefore, a high shielding effect of the wide-angle beams corresponding to the upper side of the in-vehicle display screen should be ensured as much as possible. Similarly, it may be understood that an amount of wide-angle beams correspondingly emitted from a right side of the screen (which may be understood as the second side of the first light-emitting element 31 in the first direction X or a front passenger seat) may be greater than an amount of wide-angle beams correspondingly emitted from a lower side of the screen (which may be understood as the second side of the first light-emitting element 31 in the second direction Y or a driver's seat), ensuring that the driver has a good line of sight in the vehicle. Moreover, to ensure the driving safety of the driver on the driver's seat of the vehicle and in consideration of viewing the screen of the display panel from the front passenger seat of the vehicle, the front passenger seat can allow more wide-angle beams emitted from the display panel.

Optionally, the openings 21 include first openings 211, and the light-emitting elements 30 include first light-emitting elements 31. In the thickness direction of the display panel, a first light-emitting element 31 partially overlaps a first opening 211, and a center O1 of the first light-emitting element 31 does not overlap a center O2 of the first opening 211. Please refer to the preceding embodiments for the relevant contents not repeated here. Some other specific positional relationships between the corresponding first light-emitting element 31 and first opening 211 are drawn and described by using examples.

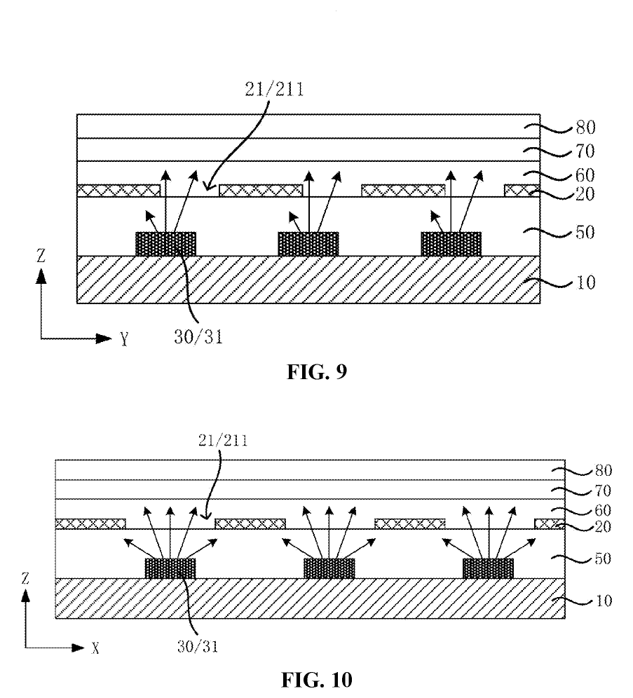

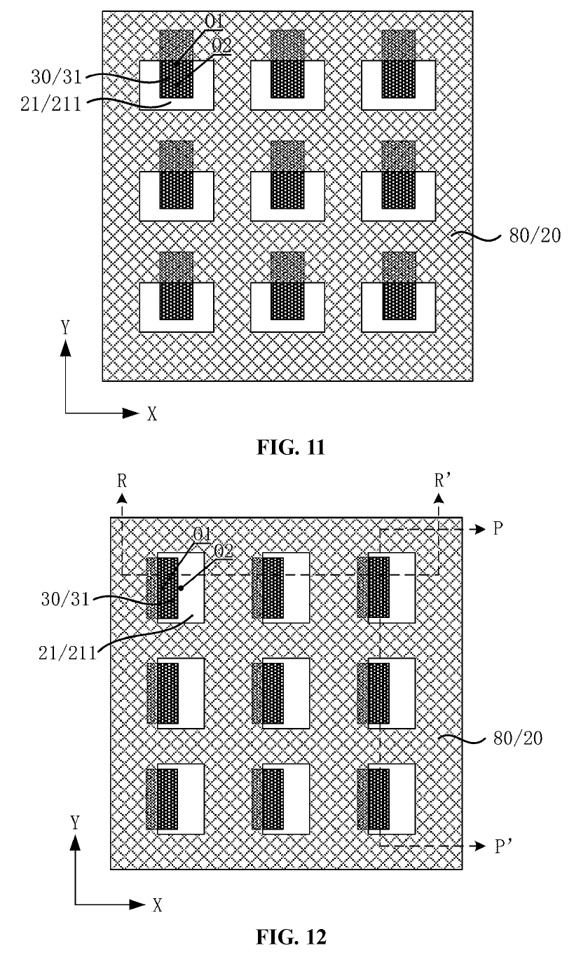

In another embodiment, optionally, FIG. 8 is a top view of another display panel according to an embodiment of the present disclosure, FIG. 9 is a section view taken along a section line FF' of the display panel of FIG. 8, and FIG. 10 is a section view taken along a section line GG' of the display panel of FIG. 8. As shown in FIGS. 8, 9 and 10, the multiple light-emitting elements 30 include at least two types of light-emitting elements 30 having different colors, and the at least two types of light-emitting elements 30 are arranged along a first direction X; for two sides of the first light-emitting element 31 along a second direction Y, a partial structure at one side of the first light-emitting element 31 along the second direction Y overlaps the light-shielding layer 20 in the thickness direction of the display panel; where the first direction X and the second direction Y are parallel to the array substrate 10 and intersect with each other.

The thickness direction of the display panel may be understood as a third direction Z. The first direction X may be understood as a direction in which at least two types of light-emitting elements 30 having different colors are sequentially arranged. The first direction X and the second direction Y intersect with each other, for example, the first direction X may be understood as a row direction of the pixel unit 40 (a row direction in which the light-emitting elements 30 are arranged), and the second direction Y may be understood as a column direction of the pixel unit 40 (a column direction in which the light-emitting elements 30 are arranged). Specifically, in the third direction Z, for the two sides of the first light-emitting element 31 along the second direction Y, the partial structure at the one side of the first light-emitting element 31 along the second direction Y overlaps the light-shielding layer 20, that is, a portion of an orthographic projection of the first light-emitting element 31 on the surface of the array substrate 10 overlaps an orthographic projection of the light-shielding layer 20 on the surface of the array substrate 10. For example, the overlap region of the projections may correspond to a partial structure at an upper side of the first light-emitting element 31 along the second direction Y (which may be understood as a partial structure of the first light-emitting element 31 facing a positive direction of the second direction Y). In this case, a center O1 of the first light-emitting element 31 does not overlap a center O2 of the first opening 211, that is, an orthographic projection of the center O1 of the first light-emitting element 31 on the surface of the array substrate 10 is misaligned with an orthographic projection of the center O2 of the first opening 211 on the surface of the array substrate 10. In a more understandable manner, the center O1 of the first light-emitting element 31 and the center O2 of the first opening 211 are arranged in the second direction Y, that is, a line connecting the center O1 of the first light-emitting element 31 and the center O2 of the first opening 211 is parallel to the second direction Y and perpendicular to the first direction X, and in the second direction Y, the center O2 of the first opening 211 is located on a lower side of the center O1 of the first light-emitting element 31 (which may be understood that the center O2 of the first opening 211 is located on a side of the center O1 of the first light-emitting element 31 facing a negative direction of the second direction Y). In other words, the misalignment of the center O1 of the first light-emitting element 31 and the center O2 of the first opening 211 may be designed in the second direction Y.

For example, the first light-emitting element 31 shown in FIG. 9 is used as an example for description. In the second direction Y, wide-angle beams corresponding to the partial structure at the upper side of the first light-emitting element 31 (which may be understood as the partial structure of the first light-emitting element 31 facing the positive direction of the second direction Y) are shielded by the light-shielding layer 20 and cannot be emitted; wide-angle beams corresponding to a partial structure at a lower side of the first light-emitting element 31 (which may be understood as a partial structure of the first light-emitting element 31 facing the negative direction of the second direction Y) are not shielded by the light-shielding layer 20 and can be emitted normally; on-axis beams or narrow-angle beams from the middle of the first light-emitting element 31 is also not shielded by the light-shielding layer 20 and can be emitted normally; shielding degrees of the light-shielding layer 20 to wide-angle beams corresponding to two sides of the first light-emitting element 31 along the first direction X are the same or approximately the same. In this manner, a light pattern of light emission of the first light-emitting element 31 can be modulated from the divergent state at various angles or various positions to the asymmetric state in the second direction Y. The above description can satisfy some particular application scenarios, for example, an in-vehicle display screen (including, but not limited to, an in-vehicle instrument screen and a central control display screen) scenario. When the display panel is applied to in-vehicle display, a particular side of the in-vehicle display screen may be an upper side of the screen, and the light-shielding layer 20 can shield wide-angle beams corresponding to the upper side of the screen, thereby solving the problem that the wide-angle beams emitted from the upper side of the in-vehicle display screen are easily reflected by the front windshield or the side window glass to form a ghost image which affects the driver's line of sight, ensuring that the driver has a good line of sight in the vehicle and can see the scene outside the vehicle, and ensuring driver's driving safety.

In another embodiment, FIG. 11 is a top view of another display panel according to an embodiment of the present disclosure. As shown in FIG. 11, compared with FIG. 8, in the case where the center O1 of the first light-emitting element 31 is misaligned with the center O2 of the first opening 211, the shape of the first opening 211 and the shape of the first light-emitting element 31 may also be reasonably selected to achieve the adjustment from the divergent light pattern to the asymmetric light pattern and achieve the modulation of the flattening and non-centrosymmetry of the light pattern. Moreover, the light emission efficiency of the first light-emitting element 31 and the brightness of the screen can also be improved.

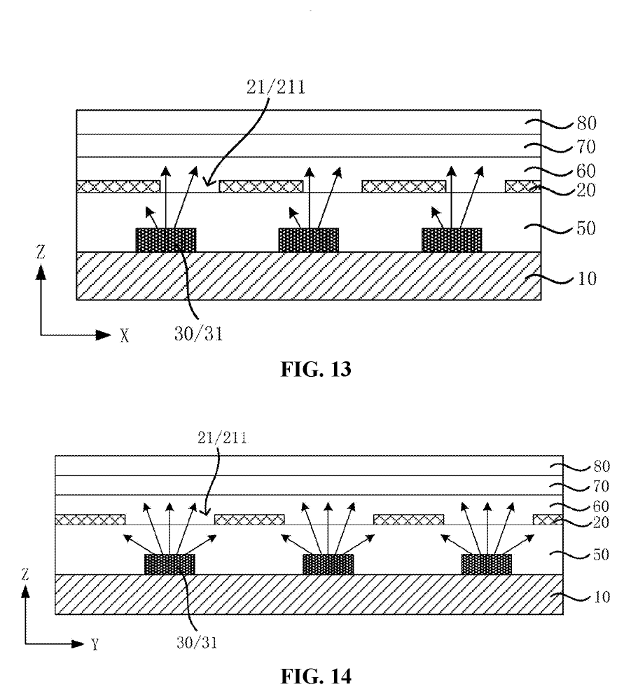

In another embodiment, optionally, FIG. 12 is a top view of another display panel according to an embodiment of the present disclosure, FIG. 13 is a section view taken along a section line RR' of the display panel of FIG. 12, and FIG. 14 is a section view taken along a section line PP' of the display panel of FIG. 12. As shown in FIGS. 12, 13 and 14, the multiple light-emitting elements 30 include at least two types of light-emitting elements 30 having different colors, and the at least two types of light-emitting elements 30 are arranged along a first direction X; for two sides of the first light-emitting element 31 along the first direction X, a partial structure at one side of the first light-emitting element 31 along the first direction X overlaps the light-shielding layer 20 in the thickness direction of the display panel.

The thickness direction of the display panel may be understood as a third direction Z, and the first direction X may be understood as a direction in which at least two types of light-emitting elements 30 having different colors are sequentially arranged. Specifically, in the third direction Z, for the two sides of the first light-emitting element 31 along the first direction X, the partial structure at the one side of the first light-emitting element 31 along the first direction X overlaps the light-shielding layer 20, that is, a portion of an orthographic projection of the first light-emitting element 31 on the surface of the array substrate 10 overlaps an orthographic projection of the light-shielding layer 20 on the surface of the array substrate 10. For example, the overlap region of the projections may correspond to a partial structure at a left side of the first light-emitting element 31 along the first direction X (which may be understood as a partial structure of the first light-emitting element 31 facing a negative direction of the first direction X). In this case, a center O1 of the first light-emitting element 31 does not overlap a center O2 of the first opening 211, that is, an orthographic projection of the center O1 of the first light-emitting element 31 on the surface of the array substrate 10 is misaligned with an orthographic projection of the center O2 of the first opening 211 on the surface of the array substrate 10. In a more understandable manner, the center O1 of the first light-emitting element 31 and the center O2 of the first opening 211 are arranged in the first direction X, that is, a line connecting the center O1 of the first light-emitting element 31 and the center O2 of the first opening 211 is parallel to the first direction X and perpendicular to the second direction Y, and in the first direction X, the center O2 of the first opening 211 is located on a right side of the center O1 of the first light-emitting element 31 (which may be understood that the center O2 of the first opening 211 is located on a side of the center O1 of the first light-emitting element 31 facing a positive direction of the first direction X). In other words, the misalignment of the center O1 of the first light-emitting element 31 and the center O2 of the first opening 211 may be designed in the first direction X.

For example, the first light-emitting element 31 shown in FIG. 13 is used as an example for description. In the first direction X, wide-angle beams corresponding to the partial structure at the left side of the first light-emitting element 31 (which may be understood as the partial structure of the first light-emitting element 31 facing the negative direction of the first direction X) are shielded by the light-shielding layer 20 and cannot be emitted; wide-angle beams corresponding to a partial structure at a right side of the first light-emitting element 31 (which may be understood as a partial structure of the first light-emitting element 31 facing the positive direction of the first direction X) are not shielded by the light-shielding layer 20 and can be emitted normally; on-axis beams or narrow-angle beams from the middle of the first light-emitting element 31 is also not shielded by the light-shielding layer 20 and can be emitted normally; shielding degrees of the light-shielding layer 20 to wide-angle beams corresponding to two sides of the first light-emitting element 31 along the second direction Y are the same or approximately the same. In this manner, a light pattern of light emission of the first light-emitting element 31 can be modulated from the divergent state at various angles or various positions to the asymmetric state in the first direction X. The above description can satisfy some particular application scenarios, for example, an in-vehicle display screen (including, but not limited to, an in-vehicle instrument screen and a central control display screen) scenario. When the display panel is applied to in-vehicle display, a particular side of the in-vehicle display screen may be a left side of the screen, and the light-shielding layer 20 can shield wide-angle beams corresponding to the left side of the screen, thereby solving the problem that the wide-angle beams emitted from the left side of the in-vehicle display screen are easily reflected by the front windshield or the side window glass to form a ghost image which affects the driver's line of sight, ensuring that the driver has a good line of sight in the vehicle and can see the scene outside the vehicle, and ensuring driver's driving safety.

In another embodiment, optionally, with continued reference to FIGS. 2, 3 and 4, the multiple light-emitting elements 30 include at least two types of light-emitting elements 30 having different colors, the at least two types of light-emitting elements 30 are arranged along a first direction X, and light-emitting elements 30 having the same color are arranged along a second direction Y; where the first direction X and the second direction Y are parallel to the array substrate 10 and intersect with each other; for two sides of the first light-emitting element 31 along the first direction X, a partial structure at one side of the first light-emitting element 31 along the first direction X overlaps the light-shielding layer 20 in the thickness direction of the display panel; for two sides of the first light-emitting element 31 along the second direction Y, a partial structure at one side of the first light-emitting element 31 along the second direction Y overlaps the light-shielding layer 20 in the thickness direction of the display panel.

Specifically, this embodiment may be essentially understood as a combination of the solutions of FIGS. 8 and 12. In the third direction Z, for the two sides of the first light-emitting element 31 along the first direction X, the partial structure at the one side of the first light-emitting element 31 along the first direction X overlaps the light-shielding layer 20, that is, a portion of an orthographic projection of the first light-emitting element 31 on the surface of the array substrate 10 overlaps an orthographic projection of the light-shielding layer 20 on the surface of the array substrate 10; for the two sides of the first light-emitting element 31 along the second direction Y, the partial structure at the one side of the first light-emitting element 31 along the second direction Y overlaps the light-shielding layer 20, that is, a portion of the orthographic projection of the first light-emitting element 31 on the surface of the array substrate 10 overlaps the orthographic projection of the light-shielding layer 20 on the surface of the array substrate 10. For example, the overlap region of the projections corresponds to both a partial structure at a left side of the first light-emitting element 31 along the first direction X (which may be understood as a partial structure of the first light-emitting element 31 facing a negative direction of the first direction X) and a partial structure at an upper side of the first light-emitting element 31 along the second direction Y (which may be understood as a partial structure of the first light-emitting element 31 facing a positive direction of the second direction Y). In this case, a center O1 of the first light-emitting element 31 does not overlap a center O2 of the first opening 211, that is, an orthographic projection of the center O1 of the first light-emitting element 31 on the surface of the array substrate 10 is misaligned with an orthographic projection of the center O2 of the first opening 211 on the surface of the array substrate 10. In a more understandable manner, the center O1 of the first light-emitting element 31 and the center O2 of the first opening 211 are arranged in an oblique direction, that is, a line connecting the center O1 of the first light-emitting element 31 and the center O2 of the first opening 211 is not parallel to the first direction X or the second direction Y. The oblique direction has an acute angle relative to the first direction X and has an acute angle relative to the second direction Y, and in the oblique direction, the center O2 of the first opening 211 is located on a lower right side of the center O1 of the first light-emitting element 31 (which may be understood that the center O2 of the first opening 211 is located on a side of the center O1 of the first light-emitting element 31 facing a positive direction of the first direction X and a negative direction of the second direction Y). In other words, the misalignment of the center O1 of the first light-emitting element 31 and the center O2 of the first opening 211 may be designed in the oblique direction.

For example, the first light-emitting element 31 shown in FIGS. 3 and 4 is used as an example for description. The above description can satisfy some particular application scenarios, for example, an in-vehicle display screen (including, but not limited to, an in-vehicle instrument screen and a central control display screen) scenario. When the display panel is applied to in-vehicle display, a particular side of the in-vehicle display screen may be a left side of the screen, and the light-shielding layer 20 can shield wide-angle beams corresponding to the left side of the screen, thereby solving the problem that the wide-angle beams emitted from the left side of the in-vehicle display screen are easily reflected by the front windshield or the side window glass to form a ghost image which affects the driver's line of sight, ensuring that the driver has a good line of sight in the vehicle and can see the scene outside the vehicle, and ensuring driver's driving safety. Similarly, a particular side of the in-vehicle display screen may be an upper side of the screen, and the light-shielding layer 20 can shield wide-angle beams corresponding to the upper side of the screen, thereby solving the problem that the wide-angle beams emitted from the upper side of the in-vehicle display screen are easily reflected by the front windshield or the side window glass to form a ghost image which affects the driver's line of sight, ensuring that the driver has a good line of sight in the vehicle and can see the scene outside the vehicle, and ensuring driver's driving safety.

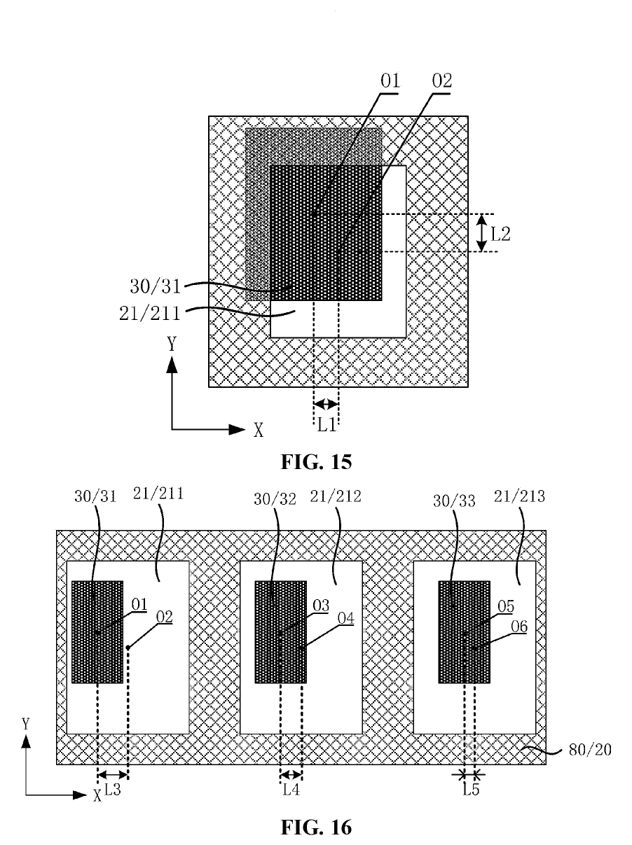

Optionally, FIG. 15 is an enlarged view of a first light-emitting element and a first opening in the display panel shown in FIG. 2. As shown in FIGS. 2, 3, 4 and 15, the multiple light-emitting elements 30 include at least two types of light-emitting elements 30 having different colors, the at least two types of light-emitting elements 30 are arranged along a first direction X, and the light-emitting elements 30 having the same color are arranged along a second direction Y; where the first direction X and the second direction Y are parallel to the array substrate 10 and intersect with each other; where L1 is a distance between the center O1 of the first light-emitting element 31 and the center O2 of the first opening 211 in the first direction X, L2 is a distance between the center O1 of the first light-emitting element 31 and the center O2 of the first opening 211 in the second direction Y, and L1 < L2.

In this case, the center O1 of the first light-emitting element 31 does not overlap the center O2 of the first opening 211, that is, the orthographic projection of the center O1 of the first light-emitting element 31 on the surface of the array substrate 10 is misaligned with the orthographic projection of the center O2 of the first opening 211 on the surface of the array substrate 10. Specifically, the distance L1 between the center O1 of the first light-emitting element 31 and the center O2 of the first opening 211 may be understood as a misaligned distance between the center O1 of the first light-emitting element 31 and the center O2 of the first opening 211 in the first direction X, and the distance L2 between the center O1 of the first light-emitting element 31 and the center O2 of the first opening 211 may be understood as a misaligned distance between the center O1 of the first light-emitting element 31 and the center O2 of the first opening 211 in the second direction Y.

Here, this embodiment defines L1 < L2, that is, the misaligned distance between the center O1 of the first light-emitting element 31 and the center O2 of the first opening 211 in the second direction Y is greater than the misaligned distance between the center O1 of the first light-emitting element 31 and the center O2 of the first opening 211 in the first direction X. Since the misaligned distance between the center O1 of the first light-emitting element 31 and the center O2 of the first opening 211 in the first direction X is different from the misaligned distance between the center O1 of the first light-emitting element 31 and the center O2 of the first opening 211 in the second direction Y, a shielding degree of the light-shielding layer 20 to wide-angle beams emitted from the first light-emitting element 31 in the second direction Y is greater than a shielding degree of the light-shielding layer 20 to the wide-angle beams emitted from the first light-emitting element 31 in the first direction X. The above description can satisfy some particular application scenarios, for example, an in-vehicle display screen (including, but not limited to, an in-vehicle instrument screen and a central control display screen) scenario. When the display panel is applied to in-vehicle display, particular sides of the in-vehicle display screen may be a left side of the screen (which may be understood as the first side of the first light-emitting element 31 in the first direction X) and an upper side of the screen (which may be understood as the first side of the first light-emitting element 31 in the second direction Y). The light-shielding layer 20 can shield wide-angle beams corresponding to the left side of the screen and wide-angle beams corresponding to the upper side of the screen, and a shielding degree of the light-shielding layer 20 to the wide-angle beams corresponding to the upper side of the screen may be greater than a shielding degree of the light-shielding layer 20 to the wide-angle beams corresponding to the left side of the screen. The reason is that the front windshield of the vehicle has an inclination angle and the wide-angle beams correspondingly emitted from the first light-emitting element 31 are more easily reflected by the front windshield. Therefore, a high shielding effect of the wide-angle beams corresponding to the upper side of the in-vehicle display screen should be ensured as much as possible. During a driving process of the vehicle, the wide-angle beams corresponding to the upper side of the screen may be mainly shielded, and the shielding of the wide-angle beams corresponding to the left side of the screen may be considered secondly. Similarly, it may be understood that an amount of wide-angle beams correspondingly emitted from a right side of the screen (which may be understood as the second side of the first light-emitting element 31 in the first direction X or a front passenger seat) may be greater than an amount of wide-angle beams correspondingly emitted from a lower side of the screen (which may be understood as the second side of the first light-emitting element 31 in the second direction Y or a driver's seat), ensuring that the driver has a good line of sight in the vehicle. Moreover, to ensure the driving safety of the driver on the driver's seat of the vehicle and in consideration of viewing the screen of the display panel from the front passenger seat of the vehicle, the front passenger seat can allow more wide-angle beams emitted from the display panel.

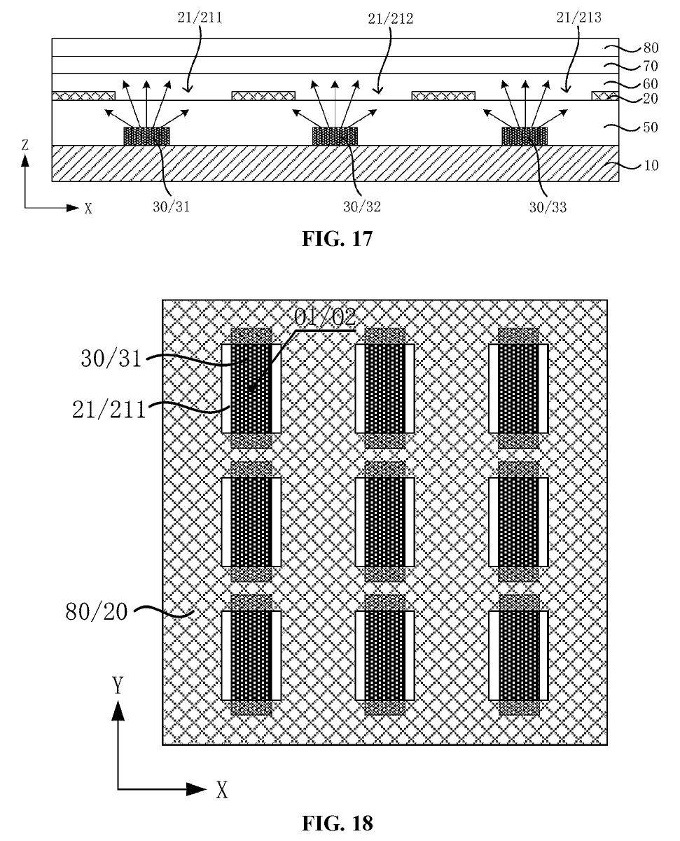

In the preceding embodiment, only the specific positional relationship between the corresponding first opening 211 and first light-emitting element 31 in one group is mentioned. Here, in this embodiment, specific positional relationships between corresponding second openings 212 and second light-emitting elements 32 in other groups and specific positional relationships between corresponding third openings 213 and third light-emitting elements 33 in other groups are described by using examples. Optionally, FIG. 16 is a top view of another display panel according to an embodiment of the present disclosure, and FIG. 17 is a section view taken along a section line QQ' of the display panel of FIG. 16. As shown in FIGS. 16 and 17, the multiple light-emitting elements 30 include at least two types of light-emitting elements 30 having different colors, and the at least two types of light-emitting elements 30 are arranged along a first direction X. The openings 21 further include second openings 212 and third openings 213, and the light-emitting elements 30 further include second light-emitting elements 32 and third light-emitting elements 33. In the thickness direction of the display panel, a second light-emitting element 32 corresponds to the second opening 212 and the second light-emitting element 32 at least partially overlaps the second opening 212, and a center O3 of the second light-emitting element 32 does not overlap a center O4 of the second opening 212. In the thickness direction of the display panel, a third light-emitting element 33 corresponds to the third opening 213 and the third light-emitting element 33 at least partially overlaps the third opening 213, and a center O5 of the third light-emitting element 33 does not overlap a center O6 of the third opening 213. The first light-emitting element 31, the second light-emitting element 32 and the third light-emitting element 33 are sequentially arranged along the first direction X. In the first direction X, a first center distance L3 is a distance between the center O1 of the first light-emitting element 31 and the center O2 of the first opening 211, a second center distance L4 is a distance between the center O3 of the second light-emitting element 32 and the center O4 of the second opening 212, a third center distance L5 is a distance between the center O5 of the third light-emitting element 33 and the center O6 of the third opening 213, and the first center distance L3, the second center distance L4 and the third center distance L5 are progressively decreased.

The first direction X may be understood as a direction in which at least two types of light-emitting elements 30 having different colors are sequentially arranged, and the first light-emitting element 31, the second light-emitting element 32 and the third light-emitting element 33 are sequentially arranged along the first direction X. Here, in this embodiment, only the arrangement order of the first light-emitting element 31, the second light-emitting element 32 and the third light-emitting element 33 is limited, and the emission colors of the first light-emitting element 31, the second light-emitting element 32 and the third light-emitting element 33, which are not specifically required and specially limited, may be selected and set as needed. The thickness direction of the display panel may be understood as a third direction Z.

In an embodiment, in the third direction Z, the first light-emitting element 31 corresponds to the first opening 211, and the first light-emitting element 31 completely overlaps the first opening 211, that is, an entire orthographic projection of the first light-emitting element 31 on the surface of the array substrate 10 is located within an orthographic projection of the first opening 211 on the surface of the array substrate 10. The second light-emitting element 32 corresponds to the second opening 212, and the second light-emitting element 32 completely overlaps the second opening 212, that is, an entire orthographic projection of the second light-emitting element 32 on the surface of the array substrate 10 is located within an orthographic projection of the second opening 212 on the surface of the array substrate 10. The third light-emitting element 33 corresponds to the third opening 213, and the third light-emitting element 33 completely overlaps the third opening 213, that is, an entire orthographic projection of the third light-emitting element 33 on the surface of the array substrate 10 is located within an orthographic projection of the third opening 213 on the surface of the array substrate 10. In another embodiment, in the third direction Z, the first light-emitting element 31 corresponds to the first opening 211, and the first light-emitting element 31 partially overlaps the first opening 211, that is, a portion of an orthographic projection of the first light-emitting element 31 on the surface of the array substrate 10 overlaps an orthographic projection of the first opening 211 on the surface of the array substrate 10; the second light-emitting element 32 corresponds to the second opening 212, and the second light-emitting element 32 partially overlaps the second opening 212. That is, a portion of an orthographic projection of the second light-emitting element 32 on the surface of the array substrate 10 overlaps an orthographic projection of the second opening 212 on the surface of the array substrate 10. The third light-emitting element 33 corresponds to the third opening 213, and the third light-emitting element 33 partially overlaps the third opening 213, that is, a portion of an orthographic projection of the third light-emitting element 33 on the surface of the array substrate 10 overlaps an orthographic projection of the third opening 213 on the surface of the array substrate 10. It is also to be noted that a partial overlap region of the first light-emitting element 31 and the first opening 211, a partial overlap region of the second light-emitting element 32 and the second opening 212 and a partial overlap region of the third light-emitting element 33 and the third opening 213 may be selected and set as needed and are not drawn for description here in this embodiment.

With continued reference to FIGS. 16 and 17, the center O1 of the first light-emitting element 31 does not overlap the center O2 of the first opening 211, that is, an orthographic projection of the center O1 of the first light-emitting element 31 on the surface of the array substrate 10 is misaligned with an orthographic projection of the center O2 of the first opening 211 on the surface of the array substrate 10, and in the first direction X, the first center distance L3 is the distance between the center O1 of the first light-emitting element 31 and the center O2 of the first opening 211. The center O3 of the second light-emitting element 32 does not overlap the center O4 of the second opening 212, that is, an orthographic projection of the center O3 of the second light-emitting element 32 on the surface of the array substrate 10 is misaligned with an orthographic projection of the center O4 of the second opening 212 on the surface of the array substrate 10, and in the first direction X, the second center distance L4 is the distance between the center O3 of the second light-emitting element 32 and the center O4 of the second opening 212. The center O5 of the third light-emitting element 33 does not overlap the center O6 of the third opening 213, that is, an orthographic projection of the center O5 of the third light-emitting element 33 on the surface of the array substrate 10 is misaligned with an orthographic projection of the center O6 of the third opening 213 on the surface of the array substrate 10, and in the first direction X, the third center distance L5 is the distance between the center O5 of the third light-emitting element 33 and the center O6 of the third opening 213.

Moreover, this embodiment defines here that in the first direction X, the first center distance L3, the second center distance L4 and the third center distance L5 are progressively decreased. Therefore, shielding degrees of the light-shielding layer 20 to wide-angle beams of the first light-emitting element 31, wide-angle beams of the second light-emitting element 32 and wide-angle beams of the third light-emitting element 33 are different. The center distances are set in a gradient misalignment manner, and an amount of the wide-angle beams correspondingly emitted from the first light-emitting element 31 in the first direction X, an amount of the wide-angle beams correspondingly emitted from the second light-emitting element 32 in the first direction X and an amount of the wide-angle beams correspondingly emitted from the third light-emitting element 33 in the first direction X also exhibit a trend of progressive increase or progressive decrease, thereby further satisfying requirements for light emission at different angles or different positions. The above description can satisfy some particular application scenarios, for example, an in-vehicle display screen (including, but not limited to, an in-vehicle instrument screen and a central control display screen) scenario. When the display panel is applied to in-vehicle display, a particular side of the in-vehicle display screen may be a left side of the screen, and the light-shielding layer 20 can shield wide-angle beams corresponding to the left side of the screen, thereby solving the problem that the wide-angle beams emitted from the left side of the in-vehicle display screen are easily reflected by the front windshield or the side window glass to form a ghost image which affects the driver's line of sight, ensuring that the driver has a good line of sight in the vehicle and can see the scene outside the vehicle, and ensuring driver's driving safety. In consideration of viewing the screen of the display panel from the front passenger seat of the vehicle, the front passenger seat can allow more wide-angle beams emitted from the display panel. Therefore, the farther the light-emitting element 30 from the front passenger seat may be, the longer the distance between the center of the light-emitting element 30 and the center of the corresponding opening 21 in the first direction X may be. For example, the first light-emitting element 31, the second light-emitting element 32 and the third light-emitting element 33 are used as an example for description. The first light-emitting element 31 is farthest from the front passenger seat, and the third light-emitting element 33 is closest to the front passenger seat. The distance between the center O1 of the first light-emitting element 31 and the center O2 of the first opening 211 in the first direction X is greater than the distance between the center O3 of the second light-emitting element 32 and the center O4 of the second opening 212 in the first direction X, and the distance between the center O3 of the second light-emitting element 32 and the center O4 of the second opening 212 in the first direction X is greater than the distance between the center O5 of the third light-emitting element 33 and the center O6 of the third opening 213 in the first direction X. That is, the first center distance L3 is greater than the second center distance L4, and the second center distance L4 is greater than the third center distance L5. It may be understood that relatively large spacing between a second side of the first light-emitting element 31 in the first direction X and an edge of the first opening 211 is needed, that is, a relatively large misalignment degree between the first light-emitting element 31 and the first opening 211 is needed. In this manner, it can be ensured that the wide-angle beams correspondingly emitted from the first light-emitting element 31 in the first direction X is more projected to the front passenger seat. Relatively large spacing between a second side of the third light-emitting element 33 in the first direction X and an edge of the third opening 213 is not needed, that is, in the case of a relatively small misalignment degree between the third light-emitting element 33 and the third opening 213, it can also be ensured that the wide-angle beams correspondingly emitted from the first light-emitting element 31 in the first direction X is projected to the front passenger seat. In a more understandable manner, in the display panel, for the light-emitting element 30 closest to the front passenger seat, for example, the third light-emitting element 33, the front passenger seat is more equivalent to receiving on-axis beams or narrow-angle beams from the third light-emitting element 33, and the misalignment degree between the third light-emitting element 33 and the third opening 213 may be relatively small without the need to excessively shield the wide-angle beams emitted from the third light-emitting element 33. It is also to be noted that the misalignment between the light-emitting element 30 and the corresponding opening 21 has little effect on a viewing effect of the user at a position of the frontal viewing angle and the problem of non-uniform left-right/up-down brightness does not occur when the display panel is viewed from the driver's seat or the front passenger seat.

In another embodiment, optionally, FIG. 18 is a top view of another display panel according to an embodiment of the present disclosure. As shown in FIG. 18, the openings 21 include first openings 211, and the light-emitting elements 30 include first light-emitting elements 31. In the thickness direction of the display panel, a first light-emitting element 31 partially overlaps a first opening 211, and a center O1 of the first light-emitting element 31 overlaps a center O2 of the first opening 211.

The thickness direction of the display panel may be understood as a third direction Z. Specifically, in the third direction Z, the first light-emitting element 31 corresponds to the first opening 211, and the first light-emitting element 31 partially overlaps the first opening 211, that is, a portion of an orthographic projection of the first light-emitting element 31 on the surface of the array substrate 10 overlaps an orthographic projection of the first opening 211 on the surface of the array substrate 10. Moreover, the center O1 of the first light-emitting element 31 overlaps the center O2 of the first opening 211, that is, an orthographic projection of the center O1 of the first light-emitting element 31 on the surface of the array substrate 10 coincides with an orthographic projection of the center O2 of the first opening 211 on the surface of the array substrate 10, thereby ensuring that shielding degrees to wide-angle beams on two sides opposite to each other with the coincident point as a symmetry center are consistent and solving the problem of the non-uniform shielding of the wide-angle beams on the two sides opposite to each other with the coincident point as the symmetry center. In addition, the coincident point can ensure that the light emission angles of the first light-emitting element 31 in all directions are uniform and ensure that the frontal viewing angle of the first light-emitting element 31 has sufficient light emission light that are uniform in all directions on the basis of shielding the wide-angle beams.

Optionally, with continued reference to FIGS. 18, in the thickness direction of the display panel, at least a portion of the first light-emitting element 31 overlaps the light-shielding layer 20.

The thickness direction of the display panel may be understood as the third direction Z. Specifically, in the third direction Z, a portion of the first light-emitting element 31 overlaps the light-shielding layer 20, that is, a portion of the orthographic projection of the first light-emitting element 31 on the surface of the array substrate 10 overlaps an orthographic projection of the light-shielding layer 20 on the surface of the array substrate 10. In this manner, the light-shielding layer 20 can effectively shield wide-angle beams emitted from the first light-emitting element 31 corresponding to this overlap region, thereby meeting the requirement of the particular side of the display panel for shielding the wide-angle beams.

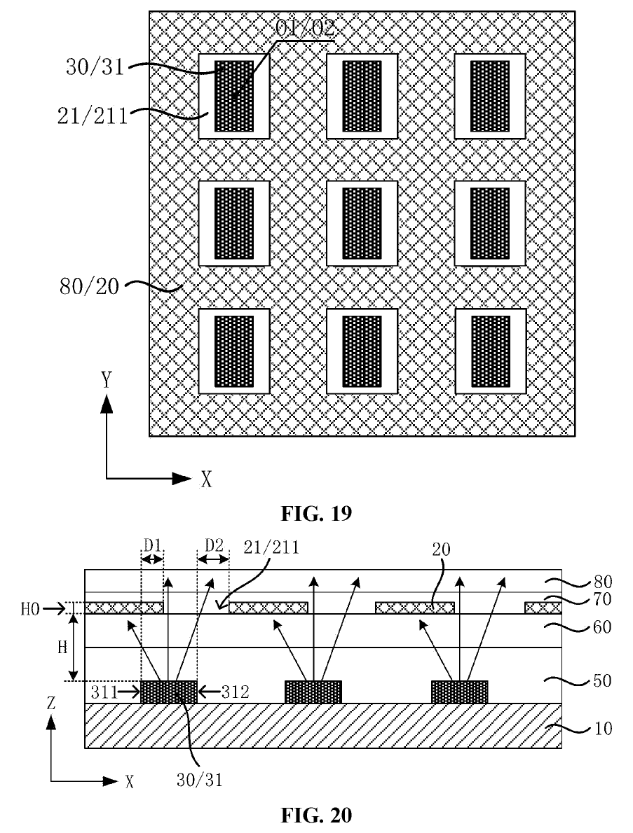

In another embodiment, optionally, FIG. 19 is a top view of another display panel according to an embodiment of the present disclosure. As shown in FIG. 19, the openings 21 include first openings 211, and the light-emitting elements 30 include first light-emitting elements 31. In the thickness direction of the display panel, a first light-emitting element 31 completely overlaps a first opening 211, and a center O1 of the first light-emitting element 31 overlaps a center O2 of the first opening 211.

The thickness direction of the display panel may be understood as a third direction Z. Specifically, in the third direction Z, the first light-emitting element 31 corresponds to the first opening 211, and the first light-emitting element 31 completely overlaps the first opening 211, that is, an entire orthographic projection of the first light-emitting element 31 on the surface of the array substrate 10 is located within an orthographic projection of the first opening 211 on the surface of the array substrate 10. Moreover, the center O1 of the first light-emitting element 31 overlaps the center O2 of the first opening 211, that is, an orthographic projection of the center O1 of the first light-emitting element 31 on the surface of the array substrate 10 coincides with an orthographic projection of the center O2 of the first opening 211 on the surface of the array substrate 10, thereby ensuring that shielding degrees to wide-angle beams on two sides opposite to each other with the coincident point as a symmetry center are consistent and solving the problem of the non-uniform shielding of the wide-angle beams on the two sides opposite to each other with the coincident point as the symmetry center. In addition, the coincident point can ensure that the light emission angles of the first light-emitting element 31 in all directions are uniform and ensure that the frontal viewing angle of the first light-emitting element 31 has sufficient light emission light that are uniform in all directions on the basis of shielding the wide-angle beams.

Optionally, with continued reference to FIG. 19, in the thickness direction of the display panel, the first light-emitting element 31 does not overlap the light-shielding layer 20.

The thickness direction of the display panel may be understood as the third direction Z. Specifically, in the third direction Z, the first light-emitting element 31 does not overlap the light-shielding layer 20, that is, the entire orthographic projection of the first light-emitting element 31 on the surface of the array substrate 10 does not overlap an orthographic projection of the light-shielding layer 20 on the surface of the array substrate 10. To achieve an effect of shielding wide-angle beams emitted from the first light-emitting element 31 by the light-shielding layer 20 shown in FIG. 19, a distance between the light-shielding layer 20 and the first light-emitting element 31 in the third direction Z may be appropriately increased and may be reasonably set according to positional relationships between the light-shielding layer 20 and other film structures, thereby meeting the requirement of the particular side of the display panel for shielding the wide-angle beams.

Optionally, with continued reference to FIGS. 18 and 19, a first ratio is a ratio of a length of the first light-emitting element 31 in a first direction X to a length of the first light-emitting element 31 in a second direction Y, a second ratio is a ratio of a length of the first opening 221 in the first direction X to a length of the first opening 221 in the second direction Y, and the second ratio is greater than the first ratio. The first direction X and the second direction Y are parallel to the array substrate 10 and intersect with each other.

The first direction X and the second direction Y intersect with each other, for example, the first direction X is perpendicular to the second direction Y, the first direction X may be understood as a row direction of the pixel unit 40 (a row direction in which the light-emitting elements 30 are arranged), and the second direction Y may be understood as a column direction of the pixel unit 40 (a column direction in which the light-emitting elements 30 are arranged). Specifically, the ratio of the length of the first light-emitting element 31 in the first direction X to the length of the first light-emitting element 31 in the second direction Y is the first ratio. The length of the first light-emitting element 31 in the first direction X may be understood as a short-side length (or a minor axis length), the length of the first light-emitting element 31 in the second direction Y may be understood as a long-side length (or a major axis length), and the first ratio may be understood as a ratio of the short-side length of the first light-emitting element 31 to the long-side length of the first light-emitting element 31, that is, a horizontal-to-vertical ratio of the first light-emitting element 31. The ratio of the length of the first opening 221 in the first direction X to the length of the first opening 221 in the second direction Y is the second ratio. The length of the first opening 211 in the first direction X may be understood as a short-side length (or a minor axis length), the length of the first opening 211 in the second direction Y may be understood as a long-side length (or a major axis length), and the second ratio may be understood as a ratio of the short-side length of the first opening 211 to the long-side length of the first opening 211, that is, a horizontal-to-vertical ratio of the first opening 211.

Here, this embodiment defines that these two ratios are not equal and the second ratio is greater than the first ratio, that is, the horizontal-to-vertical ratio of the first light-emitting element 31 is less than the horizontal-to-vertical ratio of the first opening 211 (or an aspect ratio of the first light-emitting element 31 is greater than an aspect ratio of the first opening 211), thereby effectively narrowing the light emission angles of two sides of the first light-emitting element 31 that face away from each other in the first direction X or the second direction Y and meeting the requirement of the particular side of the display panel for shielding the wide-angle beams.

For example, the first light-emitting element 31 shown in FIG. 18 is used as an example for description. In the second direction Y, wide-angle beams corresponding to partial structures at the two sides of the first light-emitting element 31 that face away from each other are shielded by the light-shielding layer 20 and cannot be emitted. In the first direction X, wide-angle beams corresponding to partial structures at the two sides of the first light-emitting element 31 that face away from each other are not shielded by the light-shielding layer 20 and can be emitted normally. On-axis beams or narrow-angle beams from the middle of the first light-emitting element 31 is also not shielded by the light-shielding layer 20 and can be emitted normally. The above description can satisfy some particular application scenarios, for example, an in-vehicle display screen (including, but not limited to, an in-vehicle instrument screen and a central control display screen) scenario. When the display panel is applied to in-vehicle display, particular sides of the in-vehicle display screen may be an upper side and lower side of the screen, and the light-shielding layer 20 can shield wide-angle beams corresponding to the upper side and lower side of the screen, thereby solving the problem that the wide-angle beams emitted from the upper side and lower side of the in-vehicle display screen are easily reflected by the front windshield or the side window glass to form a ghost image which affects the driver's line of sight, ensuring that the driver has a good line of sight in the vehicle and can see the scene outside the vehicle, and ensuring driver's driving safety.

For example, the first light-emitting element 31 shown in FIG. 19 is used as an example for description. In the second direction Y, a distance between each of the partial structures at the two sides of the first light-emitting element 31 that face away from each other and the light-shielding layer 20 is relatively long, and wide-angle beams corresponding to the partial structures at the two sides of the first light-emitting element 31 that face away from each other are shielded by the light-shielding layer 20 to a great extent. In the first direction X, a distance between each of the partial structures at the two sides of the first light-emitting element 31 that face away from each other and the light-shielding layer 20 is relatively short, and a shielding degree of the light-shielding layer 20 to wide-angle beams corresponding to the partial structures at the two sides of the first light-emitting element 31 that face away from each other is relatively small and the same. On-axis beams or narrow-angle beams from the middle of the first light-emitting element 31 is also not shielded by the light-shielding layer 20 and can be emitted normally. The above description can satisfy some particular application scenarios, for example, an in-vehicle display screen (including, but not limited to, an in-vehicle instrument screen and a central control display screen) scenario. When the display panel is applied to in-vehicle display, particular sides of the in-vehicle display screen may be an upper side and lower side of the screen, and the light-shielding layer 20 can shield wide-angle beams corresponding to the upper side and lower side of the screen, thereby solving the problem that the wide-angle beams emitted from the upper side and lower side of the in-vehicle display screen are easily reflected by the front windshield or the side window glass to form a ghost image which affects the driver's line of sight, ensuring that the driver has a good line of sight in the vehicle and can see the scene outside the vehicle, and ensuring driver's driving safety.

With continued reference to FIGS. 18 and 19, the length of the first light-emitting element 31 in the first direction X is less than the length of the first light-emitting element 31 in the second direction Y, and the length of the first opening 211 in the first direction X is less than the length of the first opening 211 in the second direction Y; where the first direction X and the second direction Y are parallel to the array substrate 10 and intersect with each other.

Specifically, this embodiment essentially provides a posture of a positional relationship between the corresponding first light-emitting element 31 and first opening 211. The length of the first light-emitting element 31 in the first direction X may be understood as the short-side length (or the minor axis length), and the length of the first opening 211 in the first direction X may be understood as the short-side length (or the minor axis length), that is, a relatively short side of the first light-emitting element 31 and a relatively short side of the first opening 211 may be set parallel to the first direction X. Specific side lengths of the first light-emitting element 31 and the first opening 211 in the first direction X and a specific ratio relationship between the first light-emitting element 31 and the first opening 211 in the first direction X may be selected and set as needed. The length of the first light-emitting element 31 in the second direction Y may be understood as the long-side length (or the major axis length), and the length of the first opening 211 in the second direction Y may be understood as the long-side length (or the major axis length), that is, a relatively long side of the first light-emitting element 31 and a relatively long side of the first opening 211 may be set parallel to the second direction Y. Specific side lengths of the first light-emitting element 31 and the first opening 211 in the second direction Y and a specific ratio relationship between the first light-emitting element 31 and the first opening 211 in the second direction Y may be selected and set as needed.

Moreover, optionally, with continued reference to FIG. 11, a length of the first light-emitting element 31 in the first direction X is less than a length of the first light-emitting element 31 in the second direction Y, and a length of the first opening 211 in the first direction X is greater than a length of the first opening 211 in the second direction Y; where the first direction X and the second direction Y are parallel to the array substrate 10 and intersect with each other.

Specifically, this embodiment essentially provides a posture of another positional relationship between the corresponding first light-emitting element 31 and first opening 211. The length of the first light-emitting element 31 in the first direction X may be understood as a short-side length (or a minor axis length), and the length of the first opening 211 in the first direction X may be understood as a long-side length (or a major axis length), that is, a relatively short side of the first light-emitting element 31 and a relatively long side of the first opening 211 may be set parallel to the first direction X. The length of the first light-emitting element 31 in the second direction Y may be understood as a long-side length (or a major axis length), and the length of the first opening 211 in the second direction Y may be understood as a short-side length (or a minor axis length), that is, a relatively long side of the first light-emitting element 31 and a relatively short side of the first opening 211 may be set parallel to the second direction Y.

Optionally, with continued reference to FIGS. 2, 3 and 4, the display panel further includes a first transparent adhesive layer 50 and a second transparent adhesive layer 60; the first transparent adhesive layer 50, the second transparent adhesive layer 60 and the light-emitting elements 30 are located on the same side of the array substrate 10, and the second transparent adhesive layer 60 is located on one side of the first transparent adhesive layer 50 facing away from the array substrate 10; the light-emitting elements 30 are located in the first transparent adhesive layer 50, and the light-shielding layer 20 is located between the first transparent adhesive layer 50 and the second transparent adhesive layer 60. Further, the display panel further includes a third transparent adhesive layer 70 and a cover glass 80, where the third transparent adhesive layer 70 is located between the second transparent adhesive layer 60 and the cover glass 80.

Specifically, the multiple light-emitting elements 30 can be first transferred on a surface on one side of the array substrate 10, and the first transparent adhesive layer 50 can be filled in adjacent gaps of the light-emitting elements 30 so that the light-emitting elements 30 are located in the first transparent adhesive layer 50. The first transparent adhesive layer 50 can flatten the surface and block water and oxygen. Then, the light-shielding layer 20 may be formed on the one side of the first transparent adhesive layer 50 facing away from the array substrate 10, and the second transparent adhesive layer 60 may be formed on one side of the light-shielding layer 20 facing away from the array substrate 10. The second transparent adhesive layer 60 can block and prevent water and oxygen in the air from penetrating into the metal circuit layer to improve the high temperature and high humidity reliability of the screen of the display panel. Then, on one side of the second transparent adhesive layer 60 facing away from the array substrate 10, the adhesion to the cover glass 80 can be achieved by the third transparent adhesive layer 70.

Optionally, FIG. 20 is another section view taken along a section line AA' of the display panel of FIG. 2. As shown in FIGS. 2 and 20, the display panel further includes a first transparent adhesive layer 50 and a second transparent adhesive layer 60; the first transparent adhesive layer 50, the second transparent adhesive layer 60 and the light-emitting elements 30 are located on the same side of the array substrate 10, and the second transparent adhesive layer 60 is located on one side of the first transparent adhesive layer 50 facing away from the array substrate 10; the light-emitting elements 30 are located in the first transparent adhesive layer 50, and the light-shielding layer 20 is located on one side of the second transparent adhesive layer 60 facing away from the first transparent adhesive layer 50. Further, the display panel further includes a third transparent adhesive layer 70 and a cover glass 80, where the third transparent adhesive layer 70 is located between the second transparent adhesive layer 60 and the cover glass 80.

Specifically, the multiple light-emitting elements 30 can be first transferred on a surface on one side of the array substrate 10, and the first transparent adhesive layer 50 can be filled in adjacent gaps of the light-emitting elements 30 so that the light-emitting elements 30 are located in the first transparent adhesive layer 50. The first transparent adhesive layer 50 can flatten the surface and block water and oxygen. Then, the second transparent adhesive layer 60 may be formed on the one side of the first transparent adhesive layer 50 facing away from the array substrate 10, and the light-shielding layer 20 may be formed on one side of the second transparent adhesive layer 60 facing away from the array substrate 10. The second transparent adhesive layer 60 can block and prevent water and oxygen in the air from penetrating into the metal circuit layer to improve the high temperature and high humidity reliability of the screen of the display panel. Then, on one side of the light-shielding layer 20 facing away from the array substrate 10, the adhesion to the cover glass 80 can be achieved by the third transparent adhesive layer 70. The light-shielding layer 20 may be understood as being disposed between the second transparent adhesive layer 60 and the third transparent adhesive layer 70.

It is also to be noted that both the first transparent adhesive layer 50 and the second transparent adhesive layer 60 need to be disposed in this embodiment. The reason lies in that the transparent adhesive layer with a relatively large thickness cannot be prepared generally and is prone to warpage, and a transparent adhesive layer with a total thickness of the first transparent adhesive layer 50 and the second transparent adhesive layer 60 cannot be prepared in one go. Therefore, two transparent adhesive layers with a relatively small thickness are prepared, and the first transparent adhesive layer 50 and the second transparent adhesive layer 60 are used for facilitating the preparation of the light-shielding layer 20 and the subsequent photolithography of the opening 21. For example, a thickness of the first transparent adhesive layer 50 may be greater than a thickness of the light-emitting element 30 to ensure that the first transparent adhesive layer 50 can completely seal the light-emitting element 30 and prevent water and oxygen from entering the light-emitting element 30 and affecting the normal operation of the light-emitting element 30.

Optionally, with continued reference to FIGS. 2, 3, 4 and 20, spacing H between the light-shielding layer 20 and a light-emitting element 30 in the thickness direction of the display panel satisfies: 0 < H ≤ 50 μm.

The thickness direction of the display panel may be understood as the third direction Z. Specifically, in the third direction Z, H is the spacing between the light-shielding layer 20 and the light-emitting element 30, and 0 < H ≤ 50 μm. It may be understood that the spacing H between the light-shielding layer 20 and the light-emitting element 30 cannot be greater than 50 μm. Although larger spacing H between the light-shielding layer 20 and the light-emitting element 30 can effectively improve an effect of shielding wide-angle beams, the transparent adhesive layer (for example, the first transparent adhesive layer 50 or the second transparent adhesive layer 60) with a relatively large thickness between the light-shielding layer 20 and the light-emitting element 30 cannot be prepared and is prone to warpage, and the relative positional relationship between the opening 21 on the light-shielding layer 20 and the corresponding light-emitting element 30 may also change, resulting in a worse effect of shielding the wide-angle beams.

Optionally, with continued reference to FIGS. 2, 3, 4 and 20, a thickness H0 of the light-shielding layer 20 in the thickness direction of the display panel satisfies: 1 μm ≤ H0 ≤ 10 μm.

The thickness direction of the display panel may be understood as the third direction Z. Specifically, in the third direction Z, the thickness of the light-shielding layer 20 is H0, and 1 μm ≤ H0 ≤ 10 μm. For example, the light-shielding layer 20 may consist of a material which is a transparent adhesive material doped with carbon black light-absorbing particles and has a relatively good effect of shielding the wide-angle beams, and the thickness of the light-shielding layer 20 may be relatively small, for example, 1 μm. Alternatively, the light-shielding layer 20 may consist of a black adhesive material in a dissolved form and has a relatively poor effect of shielding the wide-angle beams, and the thickness of the light-shielding layer 20 may be relatively large, for example, 10 μm.

Optionally, with continued reference to FIGS. 2, 3, 4 and 20, a first light-emitting element 31 includes a first edge 311, the first edge 311 overlaps the light-shielding layer 20 in the thickness direction of the display panel, and spacing D1 between the first edge 311 and an edge of a first opening 211 in a direction perpendicular to the first edge 311 and parallel to the array substrate 10 satisfies: 0 ≤ D1 < L/2; where L is a length of the first light-emitting element 31 in a direction perpendicular to the first edge 311 and parallel to the array substrate 10.

For example, the first light-emitting element 31 shown in FIG. 3 is used as an example for description. The direction perpendicular to the first edge 311 and parallel to the array substrate 10 may be the first direction X. Specifically, the first edge 311 of the first light-emitting element 31 overlaps the light-shielding layer 20 in the thickness direction of the display panel, that is, the partial structure at the first side of the first light-emitting element 31 in the first direction X overlaps the light-shielding layer 20 in the third direction Z, that is, the wide-angle beams correspondingly emitted from the partial structure at the first side of the first light-emitting element 31 in the first direction X are shielded by the light-shielding layer 20 and cannot be emitted. Moreover, a length of the overlap region of the first light-emitting element 31 and the light-shielding layer 20 in the first direction X cannot exceed L/2. In other words, L is a length of the first light-emitting element 31 in the first direction X, and half or more structures of the first light-emitting element 31 cannot be located below the light-shielding layer 20 in the first direction X. Otherwise, the normal emission of on-axis beams or narrow-angle beams from the middle of the first light-emitting element 31 cannot be ensured. That is, in the thickness direction of the display panel, the center O1 of the first light-emitting element 31 does not overlap the light-shielding layer 20.

Similarly, for example, the first light-emitting element 31 shown in FIG. 4 is used as an example for description. For the first light-emitting element 31, a direction perpendicular to the first edge 311 and parallel to the array substrate 10 may be the second direction Y. Specifically, the first edge 311 of the first light-emitting element 31 overlaps the light-shielding layer 20 in the thickness direction of the display panel, that is, the partial structure at the first side of the first light-emitting element 31 in the second direction Y overlaps the light-shielding layer 20 in the third direction Z, that is, the wide-angle beams correspondingly emitted from the partial structure at the first side of the first light-emitting element 31 in the second direction Y are shielded by the light-shielding layer 20 and cannot be emitted. Moreover, a length of the overlap region of the first light-emitting element 31 and the light-shielding layer 20 in the second direction Y cannot exceed L/2. In other words, L is a length of the first light-emitting element 31 in the second direction Y, and half or more structures of the first light-emitting element 31 cannot be located below the light-shielding layer 20 in the second direction Y. Otherwise, the normal emission of on-axis beams or narrow-angle beams from the middle of the first light-emitting element 31 cannot be ensured. That is, in the thickness direction of the display panel, the center O1 of the first light-emitting element 31 does not overlap the light-shielding layer 20.

Optionally, with continued reference to FIGS. 2, 3, 4 and 20, a first light-emitting element 31 includes a second edge 312, at least a portion of the second edge 312 overlaps a first opening 211 in the thickness direction of the display panel, and spacing D2 between the second edge 312 and an edge of the first opening 211 in a direction perpendicular to the second edge 312 and parallel to the array substrate 10 satisfies: 0 < D2 ≤ 4 μm.

For example, the first light-emitting element 31 shown in FIG. 3 is used as an example for description. The direction perpendicular to the second edge 312 and parallel to the array substrate 10 may be the first direction X. Specifically, at least a portion of the second edge 312 of the first light-emitting element 31 overlaps the first opening 211 in the thickness direction of the display panel, that is, the partial structure at the second side of the first light-emitting element 31 in the first direction X overlaps the first opening 211 in the third direction Z, that is, the wide-angle beams correspondingly emitted from the partial structure at the second side of the first light-emitting element 31 in the first direction X are not shielded by the light-shielding layer 20 but emitted from the corresponding first opening 211. In this case, D2 is the spacing between the second edge 312 and the first opening 211 in the first direction X, and 0 < D2 ≤ 4 μm. The above description can satisfy some particular application scenarios, for example, an in-vehicle display screen (including, but not limited to, an in-vehicle instrument screen and a central control display screen) scenario. When the display panel is applied to in-vehicle display, a particular side of the in-vehicle display screen may be a left side of the screen, the light-shielding layer 20 can shield wide-angle beams corresponding to the left side of the screen, and the front passenger seat can allow more wide-angle beams emitted from the display panel. However, in this case, if D2 > 4 μm, the front passenger seat corresponds to more wide-angle beams, and some wide-angle beams may be even reflected by the side window glass on one side of the front passenger seat and enter human's eyes, resulting in user's additional poor experience when the user is viewing the screen of the display panel.

For example, the first light-emitting element 31 shown in FIG. 4 is used as an example for description. The direction perpendicular to the second edge 312 and parallel to the array substrate 10 may be the second direction Y. Specifically, at least a portion of the second edge 312 of the first light-emitting element 31 overlaps the first opening 211 in the thickness direction of the display panel, that is, the partial structure at the second side of the first light-emitting element 31 in the second direction Y overlaps the first opening 211 in the third direction Z, that is, the wide-angle beams correspondingly emitted from the partial structure at the second side of the first light-emitting element 31 in the second direction Y are not shielded by the light-shielding layer 20 but emitted from the corresponding first opening 211. In this case, D2 is the spacing between the second edge 312 and the first opening 211 in the second direction Y, and 0 < D2 ≤ 4 μm. The above description can satisfy some particular application scenarios, for example, an in-vehicle display screen (including, but not limited to, an in-vehicle instrument screen and a central control display screen) scenario. When the display panel is applied to in-vehicle display, a particular side of the in-vehicle display screen may be an upper side of the screen, the light-shielding layer 20 can shield wide-angle beams corresponding to the upper side of the screen, and the driver's seat can allow more wide-angle beams emitted from the display panel. However, in this case, if D2 > 4 μm, the driver's seat corresponds to more wide-angle beams, and some wide-angle beams may be even reflected by the center console and the shifting knob that are close to the driver's seat of the vehicle and enter human's eyes, resulting in user's additional poor experience when the user is viewing the screen of the display panel.

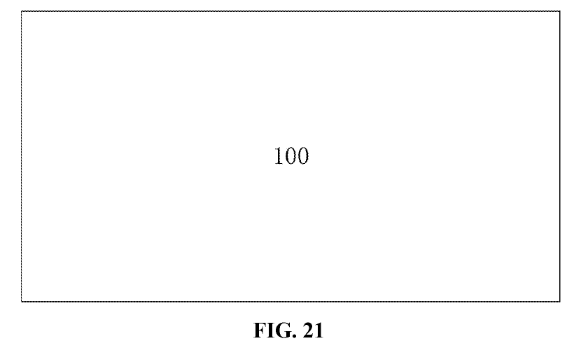

Based on the same inventive concept, an embodiment of the present disclosure provides a display device. FIG. 21 is a diagram illustrating the structure of a display device according to an embodiment of the present disclosure. As shown in FIG. 21, the display device includes the display panel 100 in any embodiment of the present disclosure. Therefore, the display device in the embodiment of the present disclosure has the beneficial effects of the display panel 100 in any embodiment of the present disclosure. The beneficial effects are not described again here. For example, the display device may be an electronic device such as an in-vehicle display device and is not limited in the embodiment of the present disclosure.

The embodiments of the present disclosure provide the display panel and the display device. The display panel includes the array substrate, the light-shielding layer and the multiple light-emitting elements. The multiple light-emitting elements are disposed on the array substrate, and the light-shielding layer is located on the one side of the multiple light-emitting elements facing away from the array substrate. The light-shielding layer includes the multiple openings. In the thickness direction of the display panel, the multiple openings at least partially overlap the multiple light-emitting elements in one-to-one correspondence, and the center of the light-emitting element among the multiple light-emitting elements overlaps the respective one of the multiple openings and does not overlap the light-shielding layer. In the display panel, the light-shielding layer with the openings is disposed on a light emission side of the light-emitting elements. The light-shielding layer can effectively adjust an angle of light emitted from the light-emitting element to meet different requirements for light emission. For example, the wide-angle beams from the light-emitting element are shielded, thereby avoiding the problem that this type of wide-angle beams are easily reflected by other objects after emission, enter the human eyes to form a reflection and generate a virtual image and interfere with the user's line of sight. Moreover, the openings on the light-shielding layer at least partially overlap the light-emitting elements in one-to-one correspondence. In this manner, the opening can ensure the emission of on-axis beams or a small viewing angle from the light-emitting element, and when the user views the display panel at a frontal or approximately frontal viewing angle, the display panel is in a normal display state, ensuring the user's good viewing experience of the display panel and an undisturbed field of view for observation of an external environment of the display panel.

It is to be noted that the preceding are preferred embodiments of the present disclosure and technical principles used therein. It is to be understood by those skilled in the art that the present disclosure is not limited to the embodiments described herein. Those skilled in the art can make various apparent modifications, adaptations, combinations, and substitutions without departing from the scope of the present disclosure. Therefore, while the present disclosure is described in detail through the preceding embodiments, the present disclosure is not limited to the preceding embodiments and may include other equivalent embodiments without departing from the concept of the present disclosure. The scope of the present disclosure is determined by the scope of the appended claims.

What is claimed is:

1. A display panel, comprising an array substrate, a light-shielding layer and a plurality of light-emitting elements; wherein the plurality of light-emitting elements are disposed on the array substrate, and the light-shielding layer is located on one side of the plurality of light-emitting elements facing away from the array substrate; and
wherein the light-shielding layer comprises a plurality of openings, in a thickness direction of the display panel, the plurality of openings at least partially overlap the plurality of light-emitting elements in one-to-one correspondence, and a center of a light-emitting element among the plurality of light-emitting elements overlaps a respective one of the plurality of openings and does not overlap the light-shielding layer.

2. The display panel according to claim 1, wherein the plurality of openings comprise first openings, and the plurality of light-emitting elements comprise first light-emitting elements; in the thickness direction of the display panel, a first light-emitting element at least partially overlaps a first opening, and a center of the first light-emitting element does not overlap a center of the first opening.

3. The display panel according to claim 2, wherein in the thickness direction of the display panel, at least a portion of the first light-emitting element overlaps the light-shielding layer.

4. The display panel according to claim 3, wherein the plurality of light-emitting elements comprise at least two types of light-emitting elements having different colors, and the at least two types of light-emitting elements are arranged along a first direction; and
for a first side and a second side of the first light-emitting element that face away from each other in the first direction, a partial structure of the first side overlaps the light-shielding layer along the thickness direction of the display panel, and a partial structure of the second side does not overlap the light-shielding layer in the thickness direction of the display panel.

5. The display panel according to claim 4, wherein for a first side and a second side of the first light-emitting element that face away from each other along a second direction, a partial structure of the first side overlaps the light-shielding layer in the thickness direction of the display panel, and a partial structure of the second side does not overlap the light-shielding layer in the thickness direction of the display panel;
wherein the first direction and the second direction are parallel to the array substrate and intersect with each other.

6. The display panel according to claim 5, wherein spacing between the second side of the first light-emitting element in the first direction and an edge of the first opening is not equal to spacing between the second side of the first light-emitting element in the second direction and an edge of the first opening.

7. The display panel according to claim 2, wherein in the thickness direction of the display panel, the first light-emitting element does not overlap the light-shielding layer.

8. The display panel according to claim 7, wherein the plurality of light-emitting elements comprise at least two types of light-emitting elements having different colors, and the at least two types of light-emitting elements are arranged along a first direction; and
for a first side and a second side of the first light-emitting element that face away from each other along the first direction, edge spacing between the first light-emitting element and the first opening at the first side along the first direction is less than edge spacing between the first light-emitting element and the first opening at the second side along the first direction.

9. The display panel according to claim 8, wherein for a first side and a second side of the first light-emitting element that face away from each other along a second direction, edge spacing between the first light-emitting element and the first opening at the first side along the second direction is less than edge spacing between the first light-emitting element and the first opening at the second side along the second direction;
wherein the first direction and the second direction are parallel to the array substrate and intersect with each other.

10. The display panel according to claim 9, wherein
the edge spacing between the first light-emitting element and the first opening at the first side in the first direction is not equal to the edge spacing between the first light-emitting element and the first opening at the first side in the second direction; and/or
the edge spacing between the first light-emitting element and the first opening at the second side in the first direction is not equal to the edge spacing between the first light-emitting element and the first opening at the second side in the second direction.

11. The display panel according to claim 2, wherein the plurality of light-emitting elements comprise at least two types of light-emitting elements having different colors, and the at least two types of light-emitting elements are arranged along a first direction; and
for two sides of the first light-emitting element along a second direction, a partial structure at one side of the first light-emitting element along the second direction overlaps the light-shielding layer in the thickness direction of the display panel; or
for two sides of the first light-emitting element along the first direction, a partial structure at one side of the first light-emitting element along the first direction overlaps the light-shielding layer in the thickness direction of the display panel;
wherein the first direction and the second direction are parallel to the array substrate and intersect with each other.

12. The display panel according to claim 2, wherein the plurality of light-emitting elements comprise at least two types of light-emitting elements having different colors, the at least two types of light-emitting elements are arranged along a first direction, and light-emitting elements having a same color are arranged along a second direction;
wherein the first direction and the second direction are parallel to the array substrate and intersect with each other;
for two sides of the first light-emitting element along the first direction, a partial structure at one side of the first light-emitting element along the first direction overlaps the light-shielding layer in the thickness direction of the display panel; and
for two sides of the first light-emitting element along the second direction, a partial structure at one side of the first light-emitting element along the second direction overlaps the light-shielding layer in the thickness direction of the display panel.

13. The display panel according to claim 2, wherein the plurality of light-emitting elements comprise at least two types of light-emitting elements having different colors, the at least two types of light-emitting elements are arranged along a first direction, and light-emitting elements having a same color are arranged along a second direction;
wherein the first direction and the second direction are parallel to the array substrate and intersect with each other; and
wherein L1 is a distance between the center of the first light-emitting element and the center of the first opening in the first direction, L2 is a distance between the center of the first light-emitting element and the center of the first opening in the second direction, and L1 < L2.

14. The display panel according to claim 2, wherein the plurality of light-emitting elements comprise at least two types of light-emitting elements having different colors, and the at least two types of light-emitting elements are arranged along a first direction;
the plurality of openings further comprise second openings and third openings, and the plurality of light-emitting elements further comprise second light-emitting elements and third light-emitting elements;
in the thickness direction of the display panel, a second light-emitting element corresponds to the second opening and the second light-emitting element at least partially overlaps the second opening, and a center of the second light-emitting element does not overlap a center of the second opening;
in the thickness direction of the display panel, a third light-emitting element corresponds to the third opening and the third light-emitting element at least partially overlaps the third opening, and a center of the third light-emitting element does not overlap a center of the third opening;
the first light-emitting element, the second light-emitting element and the third light-emitting element are sequentially arranged along the first direction; and
in the first direction, a first center distance is a distance between the center of the first light-emitting element and the center of the first opening, a second center distance is a distance between the center of the second light-emitting element and the center of the second opening, a third center distance is a distance between the center of the third light-emitting element and the center of the third opening, and the first center distance, the second center distance and the third center distance are progressively decreased.

15. The display panel according to claim 1, wherein the plurality of openings comprise first openings, and the plurality of light-emitting elements comprise first light-emitting elements;
wherein in the thickness direction of the display panel, a first light-emitting element at least partially overlaps a first opening, and a center of the first light-emitting element overlaps a center of the first opening.

16. The display panel according to claim 15, wherein a ratio of a length of the first light-emitting element in a first direction to a length of the first light-emitting element in a second direction is a first ratio, a ratio of a length of the first opening in the first direction to a length of the first opening in the second direction is a second ratio, and the second ratio is greater than the first ratio;
wherein the first direction and the second direction are parallel to the array substrate and intersect with each other.

17. The display panel according to claim 15, wherein a length of the first light-emitting element in a first direction is less than a length of the first light-emitting element in a second direction, and a length of the first opening in the first direction is greater than a length of the first opening in the second direction;
wherein the first direction and the second direction are parallel to the array substrate and intersect with each other.

18. The display panel according to claim 1, further comprising a first transparent adhesive layer and a second transparent adhesive layer;
wherein the first transparent adhesive layer, the second transparent adhesive layer and the plurality of light-emitting elements are located on a same side of the array substrate, and the second transparent adhesive layer is located on one side of the first transparent adhesive layer facing away from the array substrate; and
the plurality of light-emitting elements are located in the first transparent adhesive layer, and the light-shielding layer is located between the first transparent adhesive layer and the second transparent adhesive layer or on one side of the second transparent adhesive layer facing away from the first transparent adhesive layer.

19. The display panel according to claim 18, further comprising a third transparent adhesive layer and a cover glass, wherein the third transparent adhesive layer is located between the second transparent adhesive layer and the cover glass.

20. A display device, comprising a display panel, wherein the display panel comprises:
an array substrate, a light-shielding layer and a plurality of light-emitting elements; wherein the plurality of light-emitting elements are disposed on the array substrate, and the light-shielding layer is located on one side of the plurality of light-emitting elements facing away from the array substrate; and
wherein the light-shielding layer comprises a plurality of openings, in a thickness direction of the display panel, the plurality of openings at least partially overlap the plurality of light-emitting elements in one-to-one correspondence, and a center of a light-emitting element among the plurality of light-emitting elements overlaps a respective one of the plurality of openings and does not overlap the light-shielding layer.
